(19) United States
(12) Patent Application Publication
(10) Pub. No.: US 2009/0114269 A1
(43) Pub. Date: May 7, 2009

(54) QUICK RELEASE MECHANISM FOR SOLAR PANELS

(76) Inventors: Anne Elizabeth Fletcher, Palo Alto, CA (US); Christine Mae Concho, Barstow, CA (US); Christopher Steven Edgett, Piedmont, CA (US); Peter Rive, San Francisco, CA (US); Damien Christopher Scott, Daly City, CA (US); Ben Tarbell, Palo Alto, CA (US)

Correspondence Address: FOUNTAINHEAD LAW GROUP, PC, 900 LAFAYETTE STREET, SUITE 509, SANTA CLARA, CA, 95050, US

(21) Appl. No.: 11/936,343

(22) Filed: Nov. 7, 2007

(51) Int. Cl. H01L 31/05

(52) U.S. Cl. 136/251

(57) ABSTRACT

Some aspects of the present invention relate to an example solar energy system that includes a solar panel and a support which is secured to the solar panel such that the support may be detached from the solar panel by manually manipulating at least one of the support and the solar panel. In some embodiments, the solar energy system further includes a clamp that secures the solar panel to the support. It should be noted that the support may be adapted to be secured to a structure that includes a roof. In some embodiments, the support may be adapted to extend through the roof in order to be secured to a portion of a structure that is below the roof. The solar energy system makes it easier to install, displace and/or remove the solar panels which form the solar energy system from the structure where the solar panels are attached.

### FIELD

The present application relates generally to the field of solar energy systems and, more specifically, to solar energy systems that include solar panels.

### BACKGROUND

Most solar energy systems are composed of solar panels, various structural elements and associated mounting hardware. The appropriate size, mounting arrangement and positioning of a solar energy system will depend in part on the area where the solar energy system is to be located and the amount of power that needs to be generated by the solar energy system.

The solar panels in many solar energy systems are mounted onto the roof of a building or an adjacent structure. The amount of labor and the configuration of the hardware that is required to mount the solar panels on a roof depends in part on the type of roof and the layout of the structure where the solar energy system is located

Many solar energy systems are designed to work in parallel with an electric utility grid such that the solar energy systems generate electricity during daylight hours and draw electricity from the grid during nighttime hours. Some solar energy systems are able to set up a net metering relationship with a local utility which enables owners of such systems to sell excess power back to the utility during peak hours when rates are high and buy electricity during non-peak hours when rates are low.

Solar panels are typically made up of photovoltaic cells, which convert sunlight into DC power. The DC power from the photovoltaic cells is sent to an inverter, where it is converted into AC power, or standard electrical current. The AC power travels from the inverter to the electrical panel (or breaker box) where it is available to service a user's electrical needs.

One of the drawbacks with many solar energy systems is that it is often difficult to install and/or remove the solar panels which form the system from the structure where the solar panels are attached. An assortment of tools is often required in order to remove one or more of the solar panels from many solar energy systems. The need for tools is problematic because the tools must carried up and down from the roof and care must be taken to not to let the tools fall from the roof.

In addition, firefighters often need to remove the solar panels from the roof when fighting fires. Hauling, finding and using an assortment of tools in order to remove one or more solar panels is one of last things that firefighters should be worrying about while they are high up on a roof in a potentially dangerous firefighting situation.

### BRIEF DESCRIPTION OF THE DRAWINGS

The invention is now described, by way of non-limiting example, with reference to the accompanying diagrammatic drawings in which like reference numerals are used to indicate the same or similar features.

FIG. 1 illustrates an example solar energy system.

FIG. 2 shows the example solar energy system of FIG. 1 with some portions of the solar panels removed from a roof so that a firefighter has access to the interior of structure through the roof.

### Single Panel

FIG. 3 is a side view of another example solar energy system that includes a single solar panel.

FIG. 4 is a perspective view of the solar energy system shown in FIG. 3.

FIG. 5 is a side view illustrating an example embodiment of the solar energy system of FIG. 3 where the solar panel includes elongated members.

FIG. 6 is side view of the solar energy system shown in FIG. 5 where the solar panel and elongated members are disengaged from the supports.

FIG. 7 is an end view of the solar energy system shown in FIG. 5.

FIG. 8 is a side view illustrating another example embodiment of the solar energy system.

FIG. 9 is side view of the solar energy system shown in FIG. 8 where one side of the solar panel is disengaged from the supports.

FIG. 10 is a side view illustrating yet another example embodiment of the solar energy system.

FIG. 11 is side view of the solar energy system shown in FIG. 8 where one side of the solar panel is disengaged from the elongated member.

FIG. 12 is a side view illustrating yet another example embodiment of the solar energy system.

FIG. 13 is a perspective view of the solar energy system shown in FIG. 12.

FIG. 14 is an enlarged side view illustrating a portion of the solar energy system shown in FIG. 12.

FIG. 15 is an enlarged perspective view of the portion of the solar energy system shown in FIG. 14.

FIG. 16 is a side view illustrating still another example embodiment of the solar energy system.

FIG. 17 is a side view similar to FIG. 16 illustrating a modification to the embodiment shown in FIG. 16.

FIG. 18 is a side view similar to FIG. 16 illustrating a modification to the embodiment shown in FIG. 16.

FIG. 19 is a side view similar to FIG. 16 illustrating a modification to the embodiment shown in FIG. 16.

FIG. 20 is a side view illustrating another example embodiment of the solar energy system.

FIG. 21 is a side view similar to FIG. 20 illustrating a modification to the embodiment shown in FIG. 20.

FIG. 22 is a side view similar to FIG. 20 illustrating a modification to the embodiment shown in FIG. 20.

FIG. 23 is a side view similar to FIG. 20 illustrating a modification to the embodiment shown in FIG. 20.

FIG. 24 is a side view illustrating another example embodiment of the solar energy system.

FIG. 25 is a side view similar to FIG. 24 illustrating a modification to the embodiment shown in FIG. 24.

FIG. 26 is a side view similar to FIG. 24 illustrating a modification to the embodiment shown in FIG. 24.

FIG. 27 is a side view illustrating still another example embodiment of the solar energy system.

FIG. 28 is a side view illustrating yet another example embodiment of the solar energy system.

FIG. 29 is a side view illustrating yet another example embodiment of the solar energy system.

FIG. 30 is a side view of the solar energy system shown in FIG. 29 with the solar panels overlaying one another.

FIG. 31 is a top view of the solar energy system shown in FIG. 29 with the solar panels not overlaying one another.

FIG. 32 is a side view illustrating yet another example embodiment of the solar energy system.

FIG. 33 is a side view of the solar energy system shown in FIG. 32 with the solar panels of the solar energy system folded together.

FIG. 34 is a top view of the solar energy system shown in FIG. 32 with the solar panels of the solar energy system unfolded.

### Row of Panels

FIG. 35 is a perspective view illustrating another example embodiment of the solar energy system where the solar energy system includes a row of solar panels.

FIG. 36 is a perspective view similar to FIG. 35 illustrating a modification to the embodiment shown in FIG. 35 where one side of the row of solar panels is detached from a roof.

FIG. 37 is a perspective view similar to FIG. 35 illustrating another modification to the embodiment shown in FIG. 35 where one side of the row of solar panels is detached from a roof.

FIG. 38 illustrates an example way to rotatably attach a solar panel to an elongated member.

FIG. 39 is a perspective view of another example solar energy system where a mechanism detaches one side of a row of solar panels from a roof.

FIG. 40 is a perspective view of the solar energy system shown in FIG. 39 where the mechanism has been manipulated to detach one side of the row of solar panels from the roof.

FIG. 41 is a perspective view of another example solar energy system where the solar energy system includes an array of solar panels.

FIG. 42 is a perspective view of the solar energy system shown in FIG. 41 where both sides of one row of solar panels have been detached from a roof.

FIG. 43 is a perspective view of the solar energy system shown in FIG. 41 where one side of one row of solar panels has been detached from a roof.

### DETAILED DESCRIPTION

A solar energy system is described herein. In the following description, for purposes of explanation, numerous specific details are set forth in order to provide a thorough understanding of the present invention. It will be evident, however, to one skilled in the art that the present invention may be practiced without these specific details.

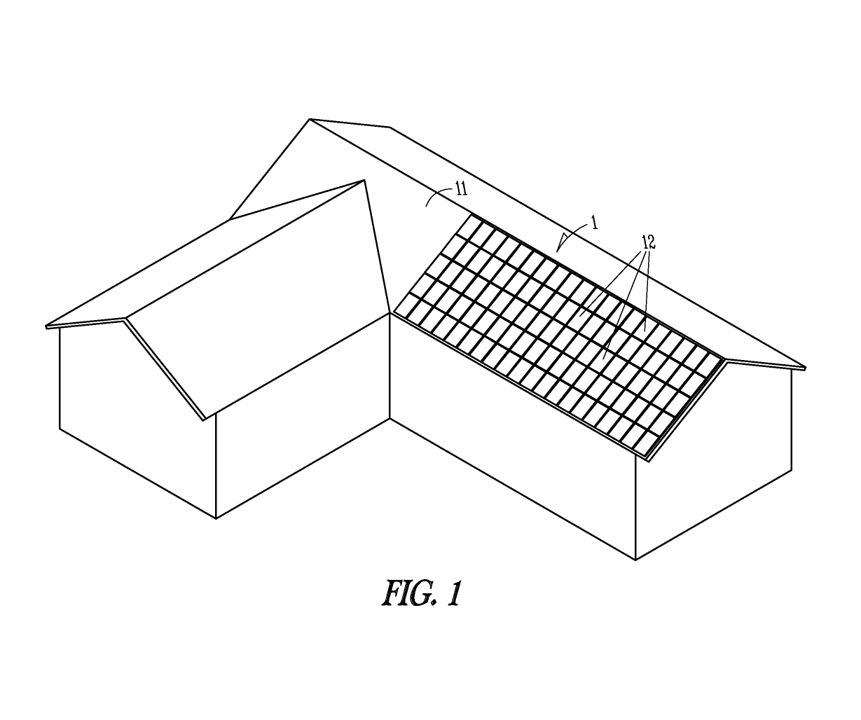

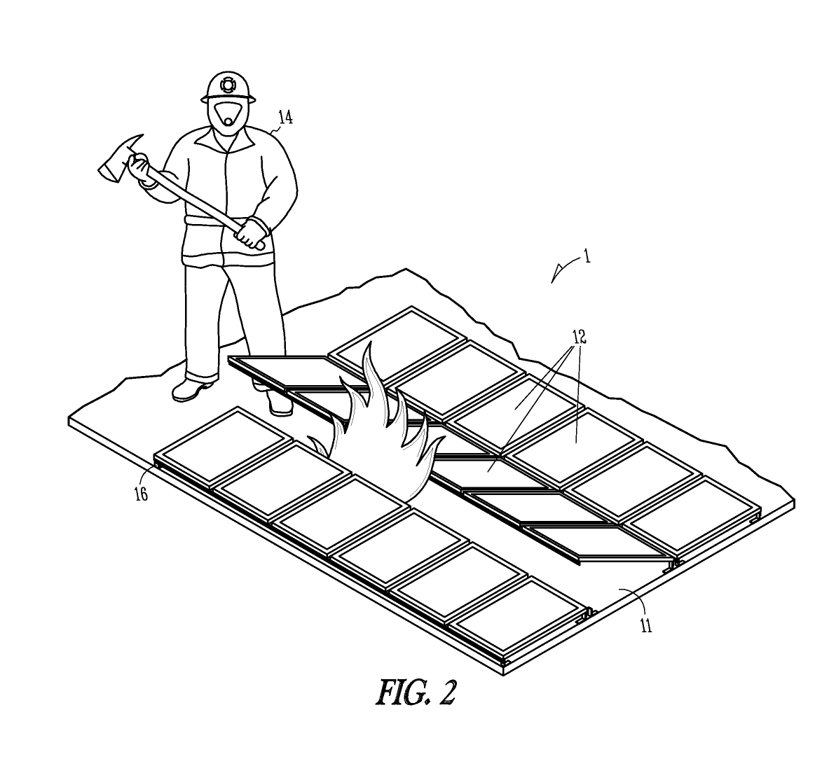

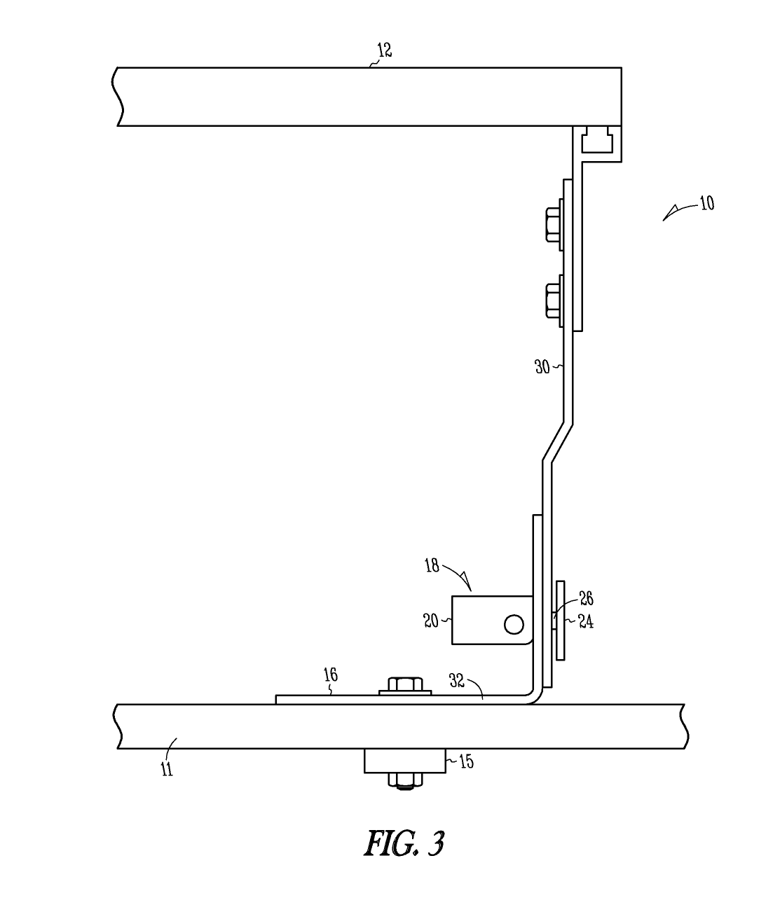

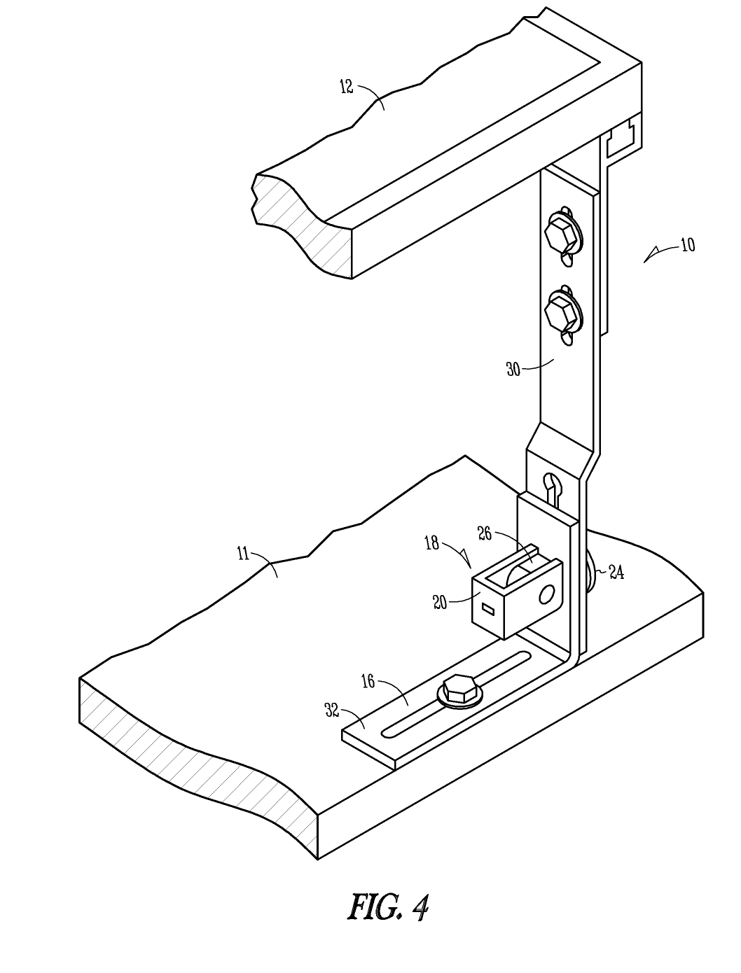

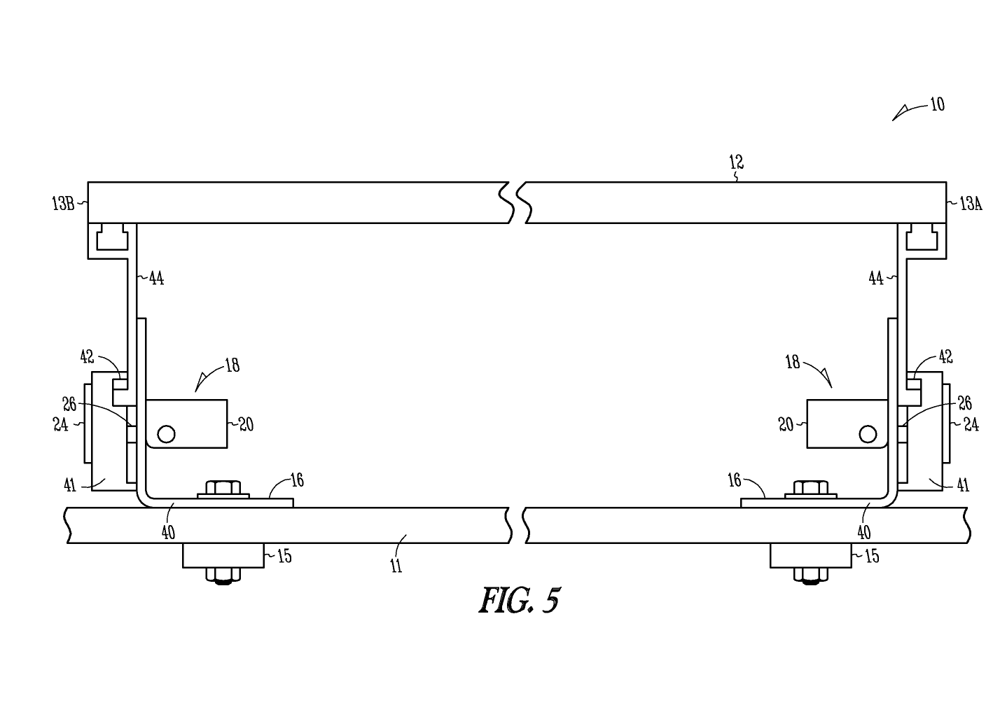

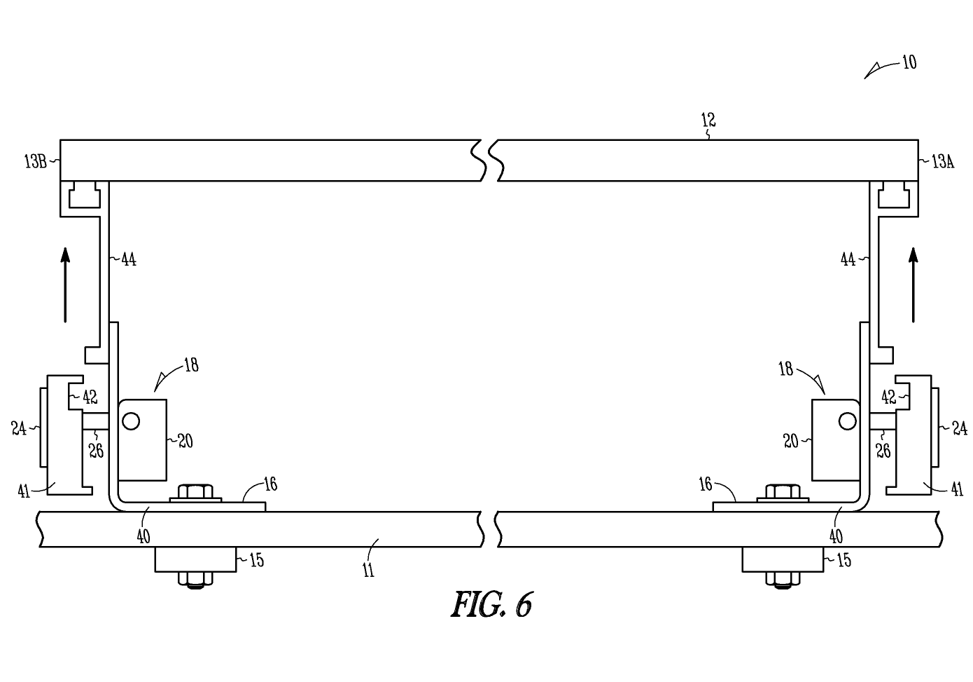

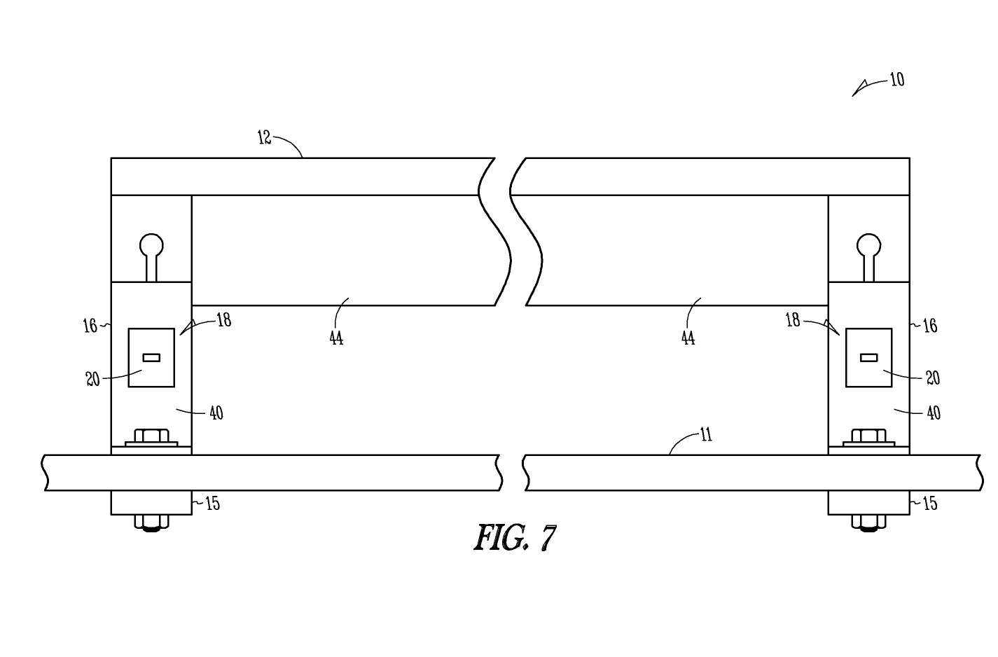

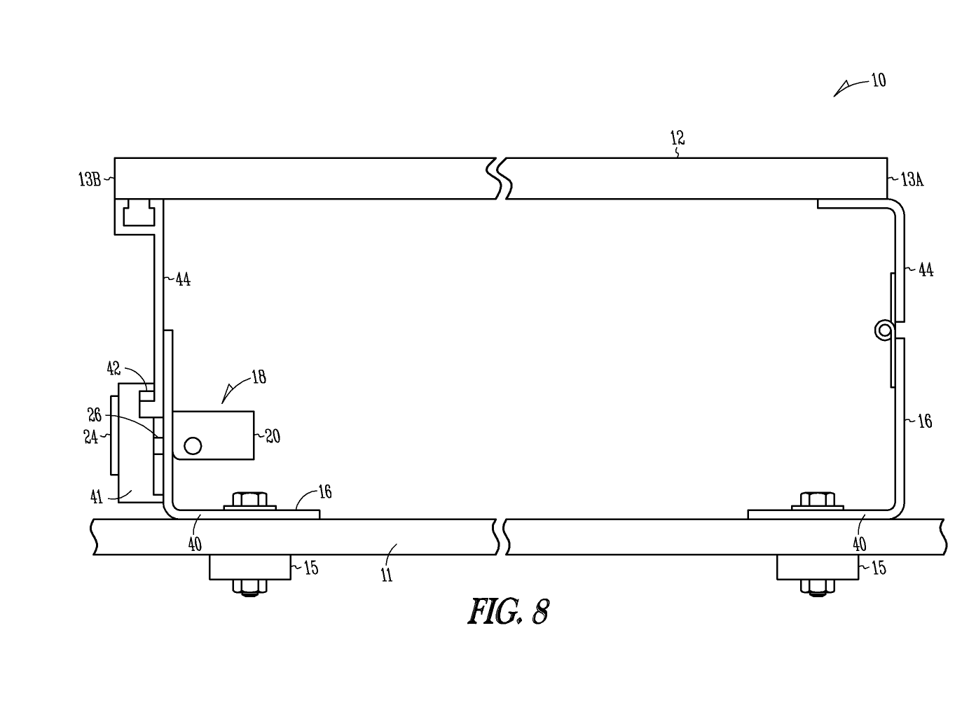

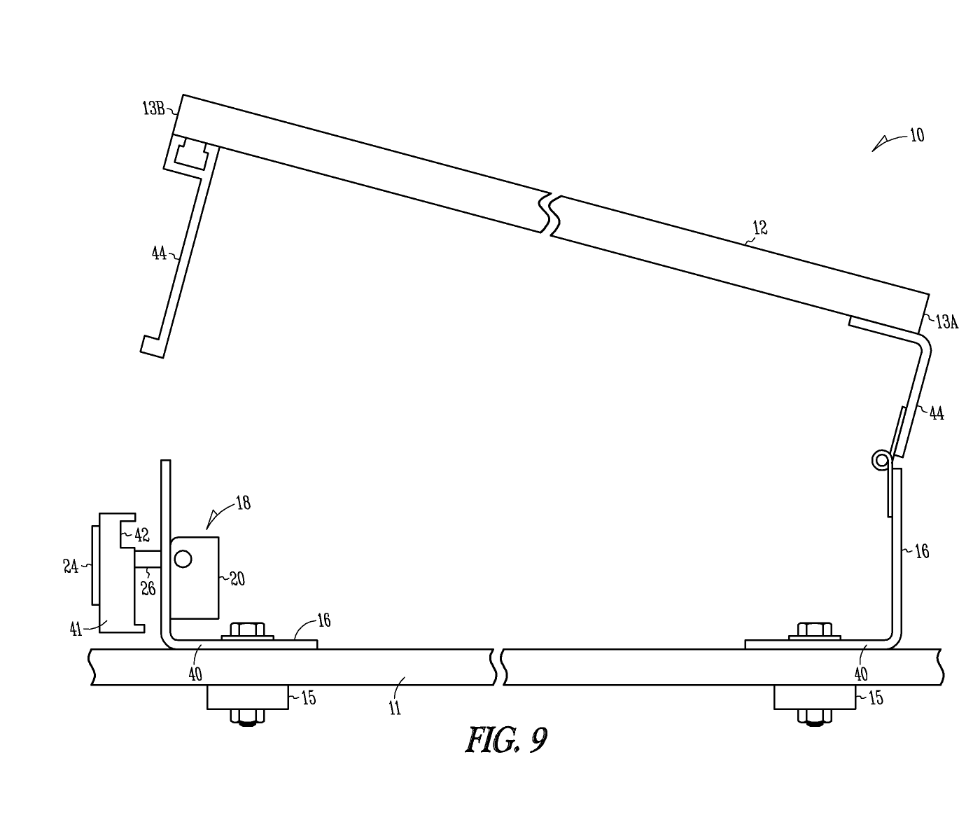

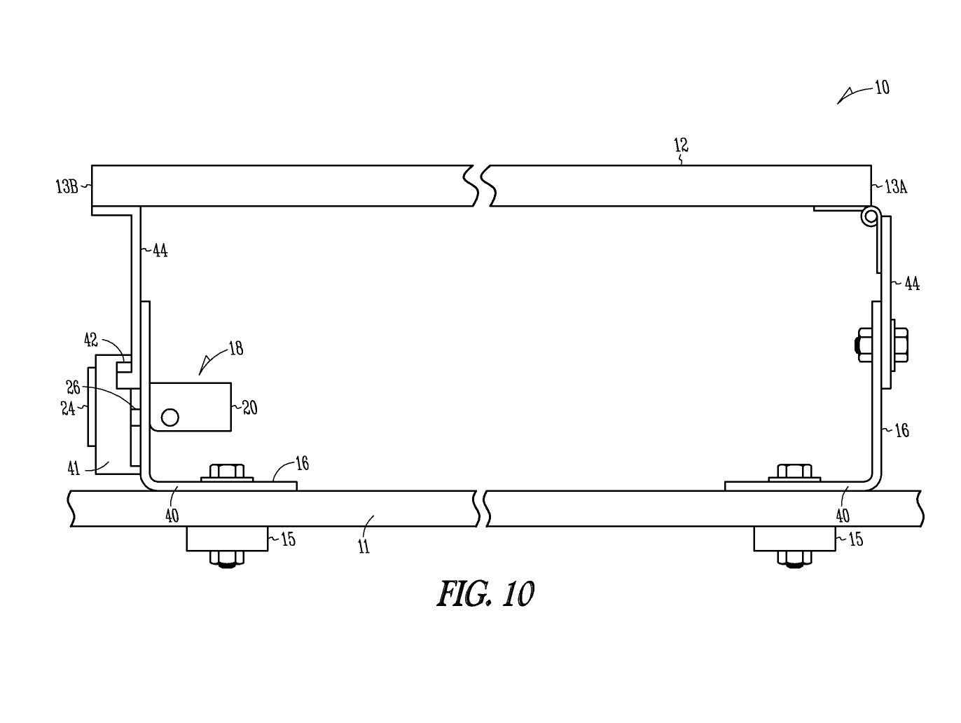

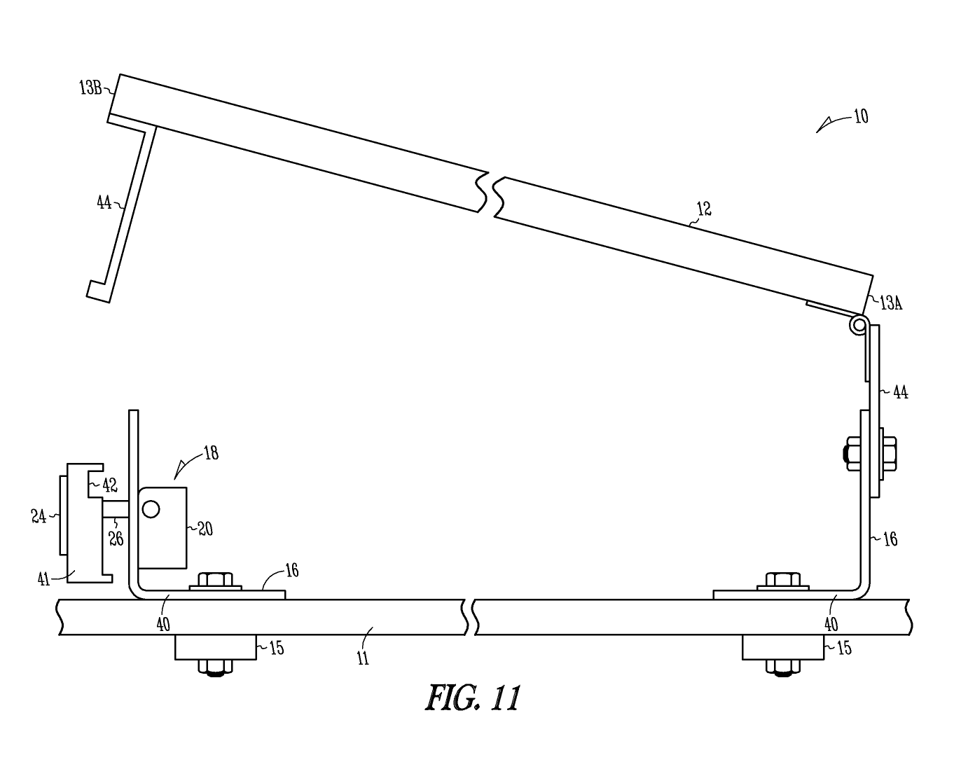

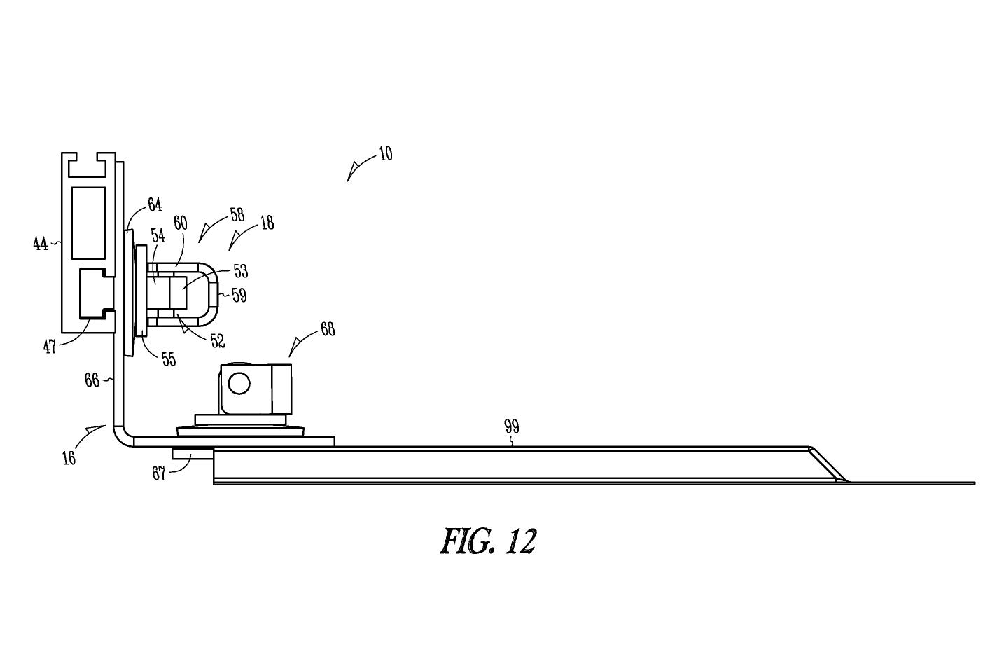

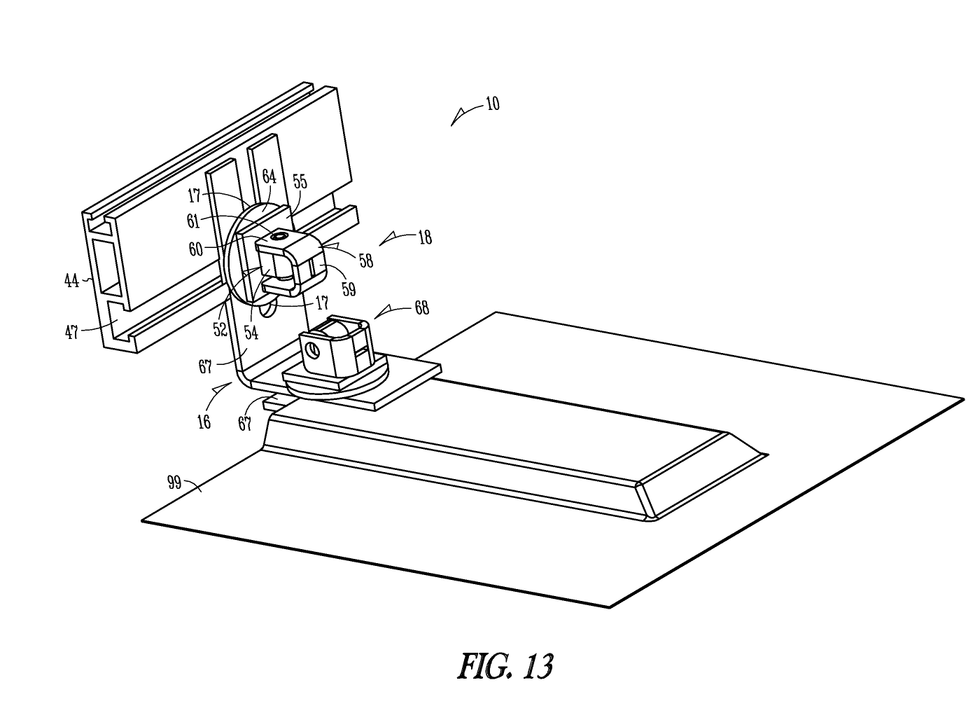

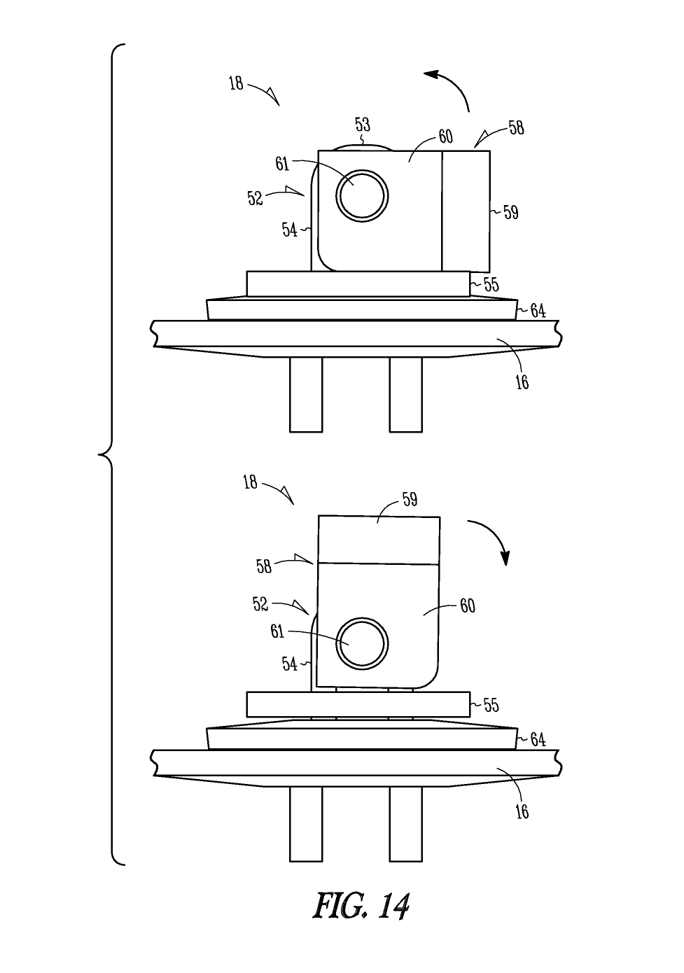

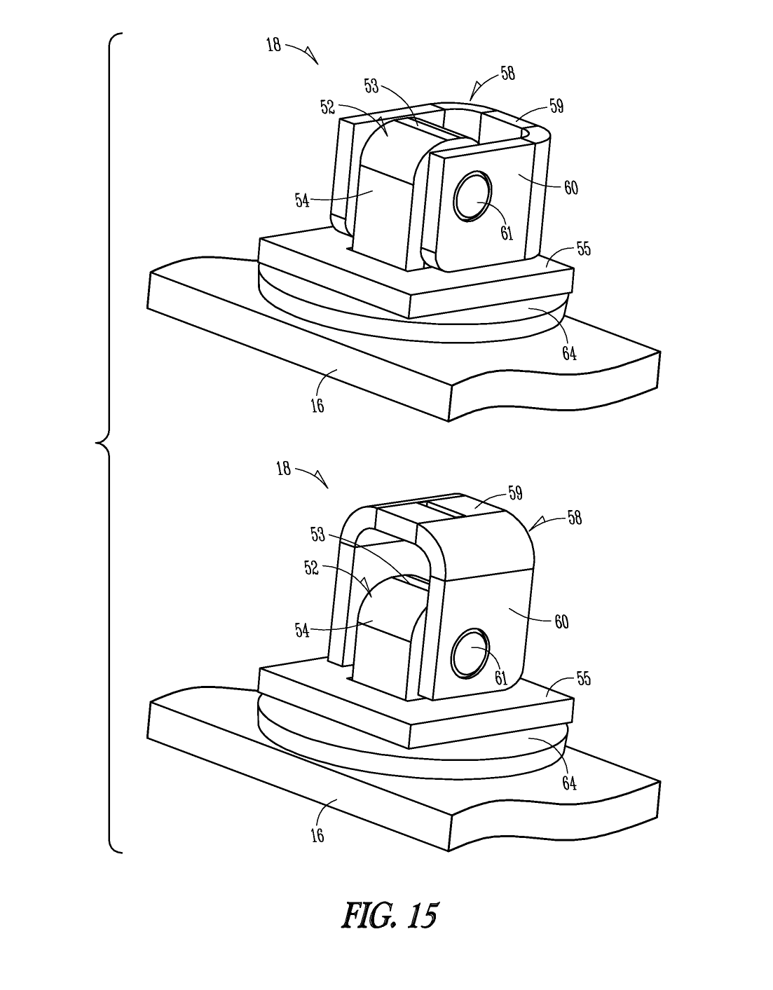

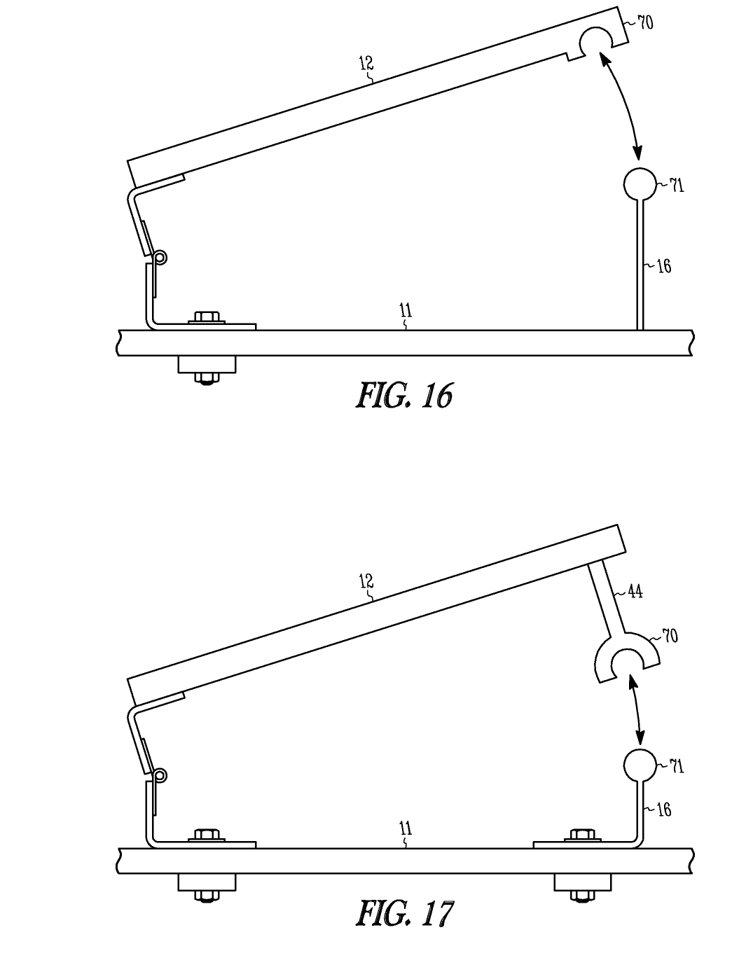

FIG. 1 illustrates an example solar energy system 1. The solar energy system 1 includes one or more solar panels 12 that are readily installed and/or removed from a structure (i. e., roof 11) where the solar panels 12 are attached. The solar panel(s) 12 may be installed and/or removed using little or no tools. The solar panels 12 are easier to install, displace and/or remove because no tools (or minimal tools) need to be carried up and down from the roof 11 and there is a reduced danger of having tools fall from the roof 11.

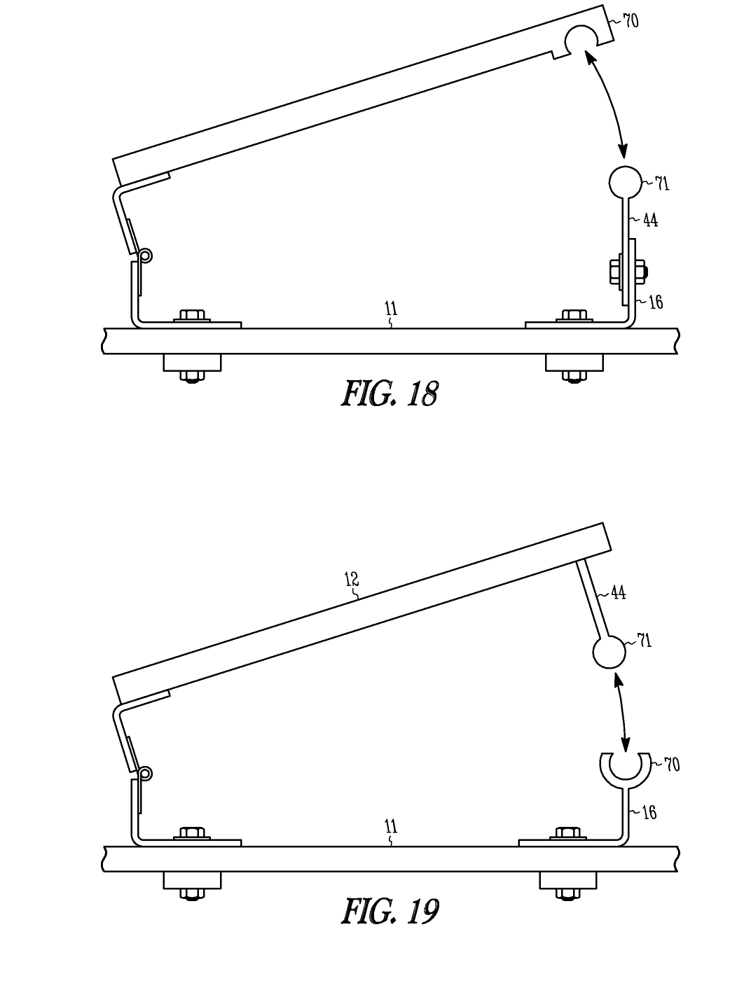

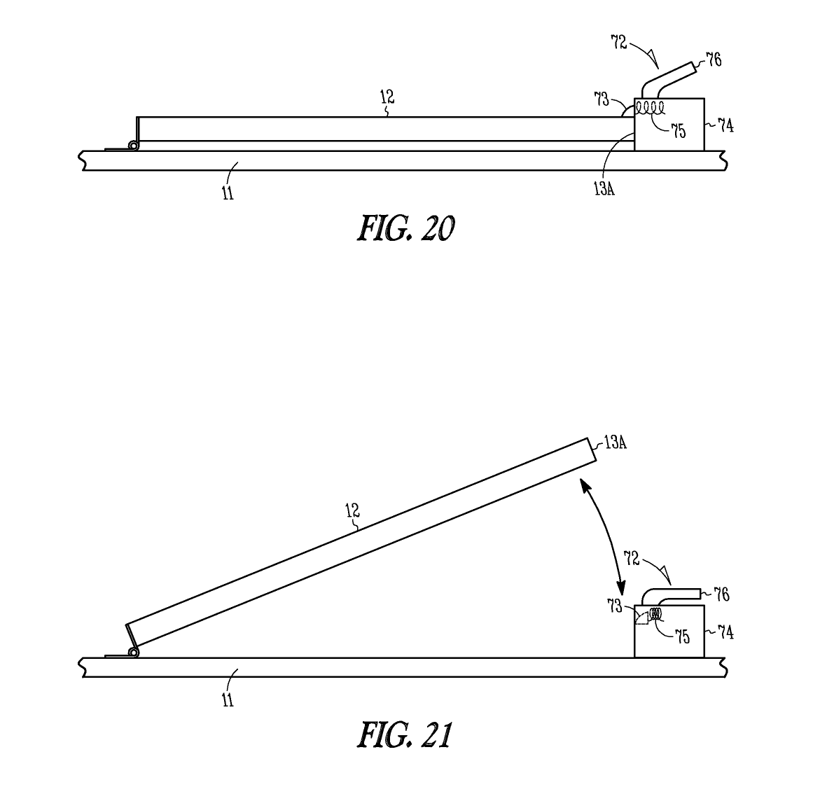

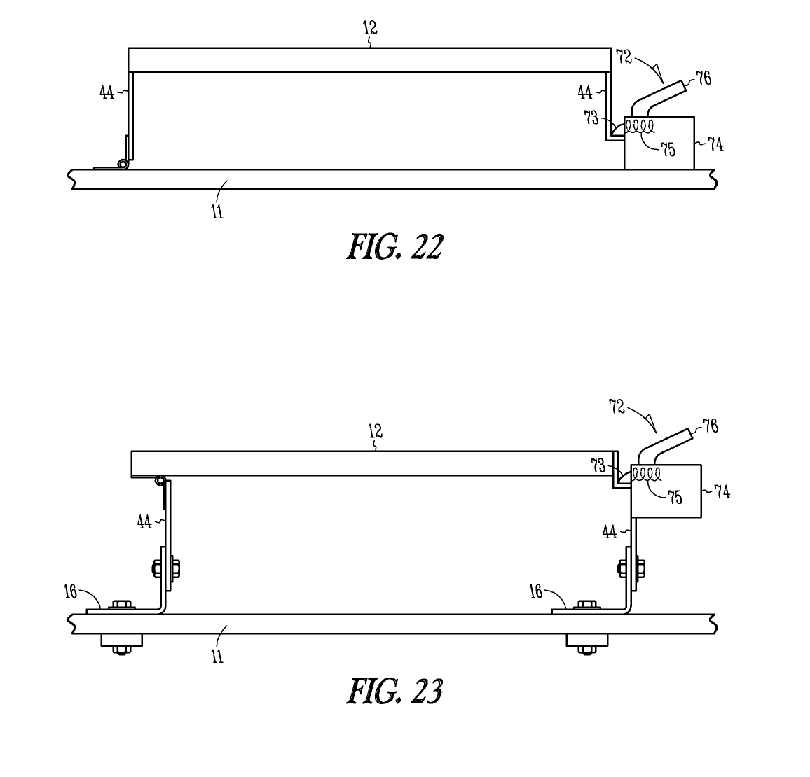

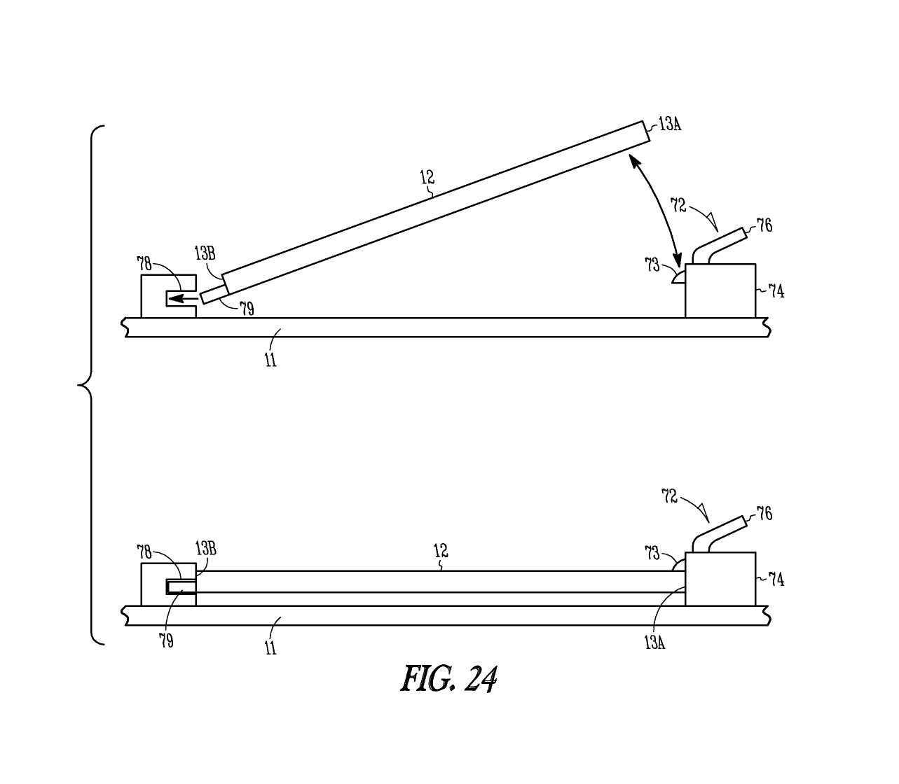

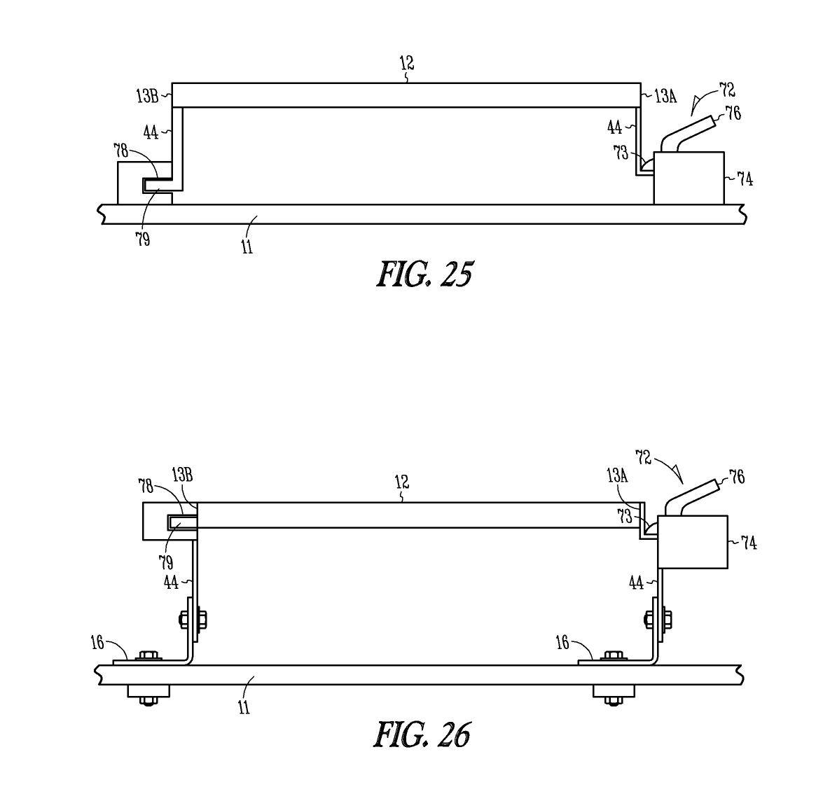

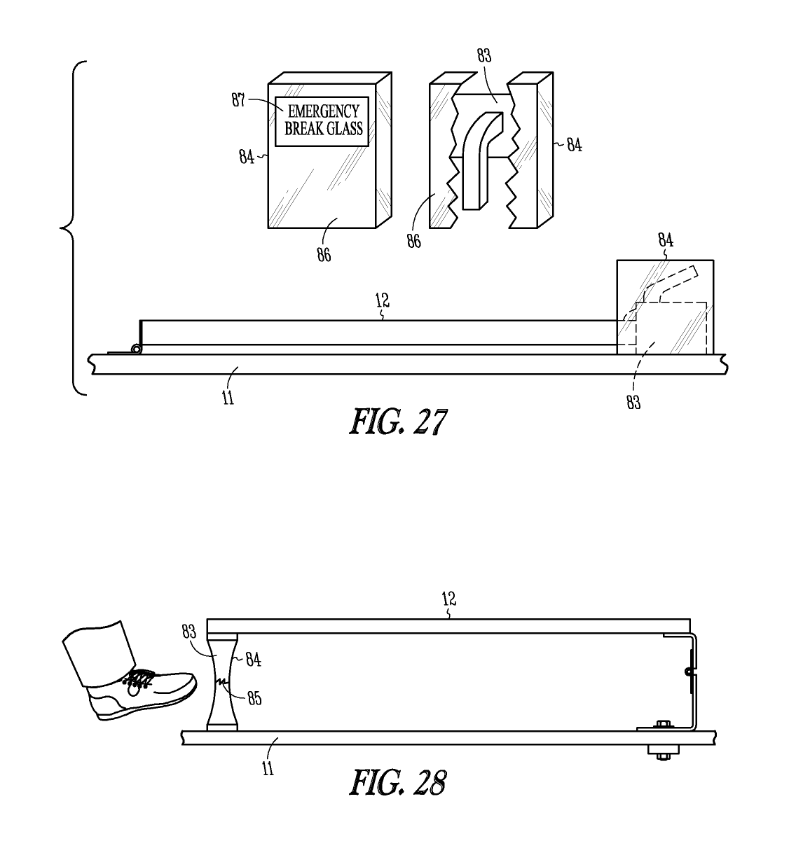

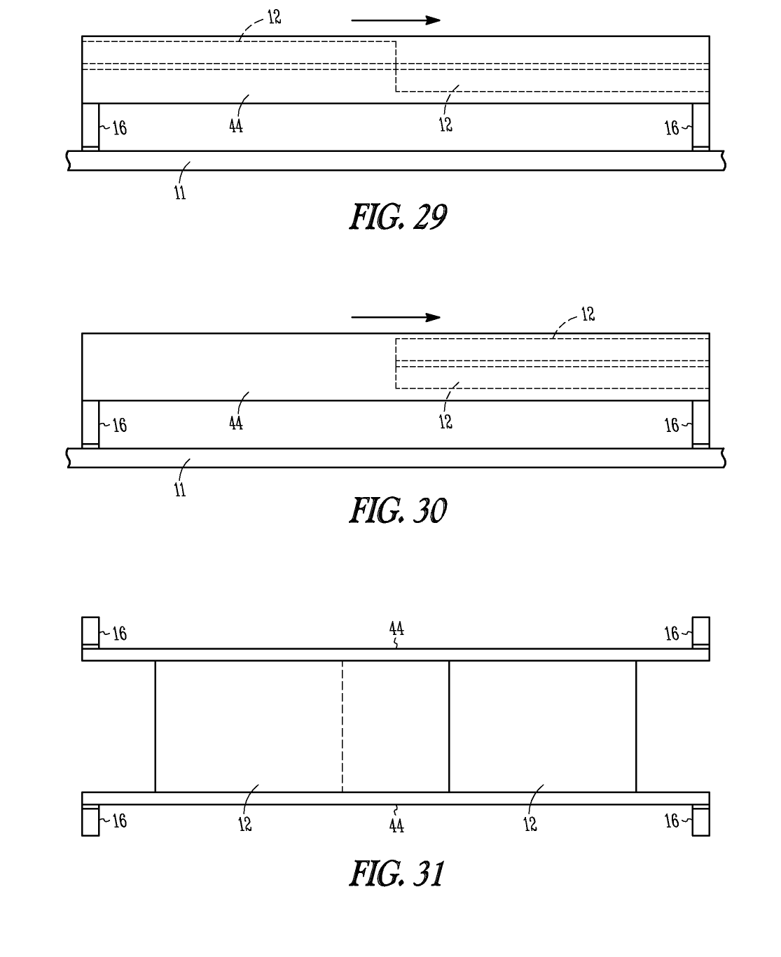

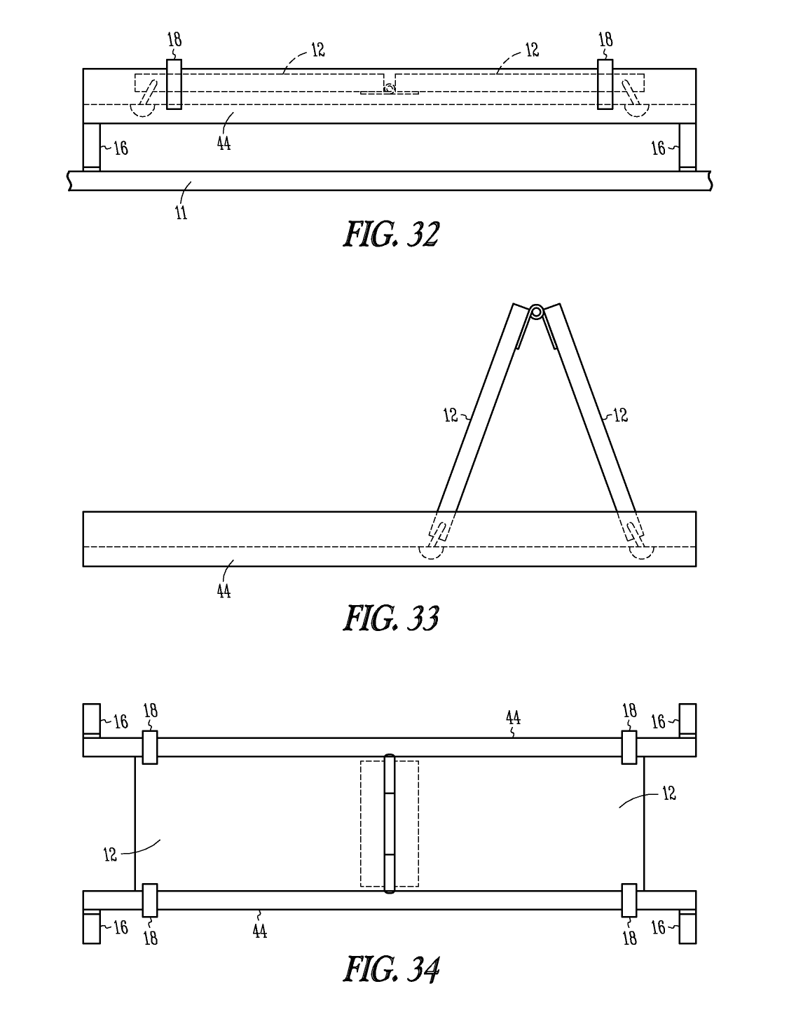

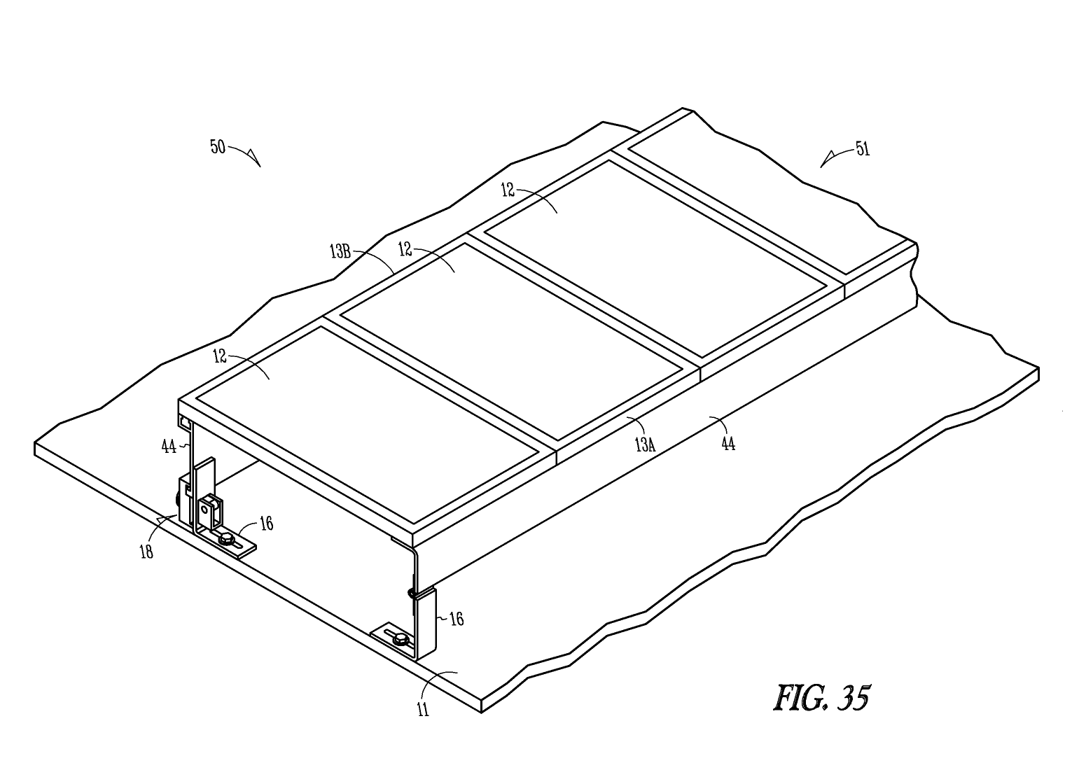

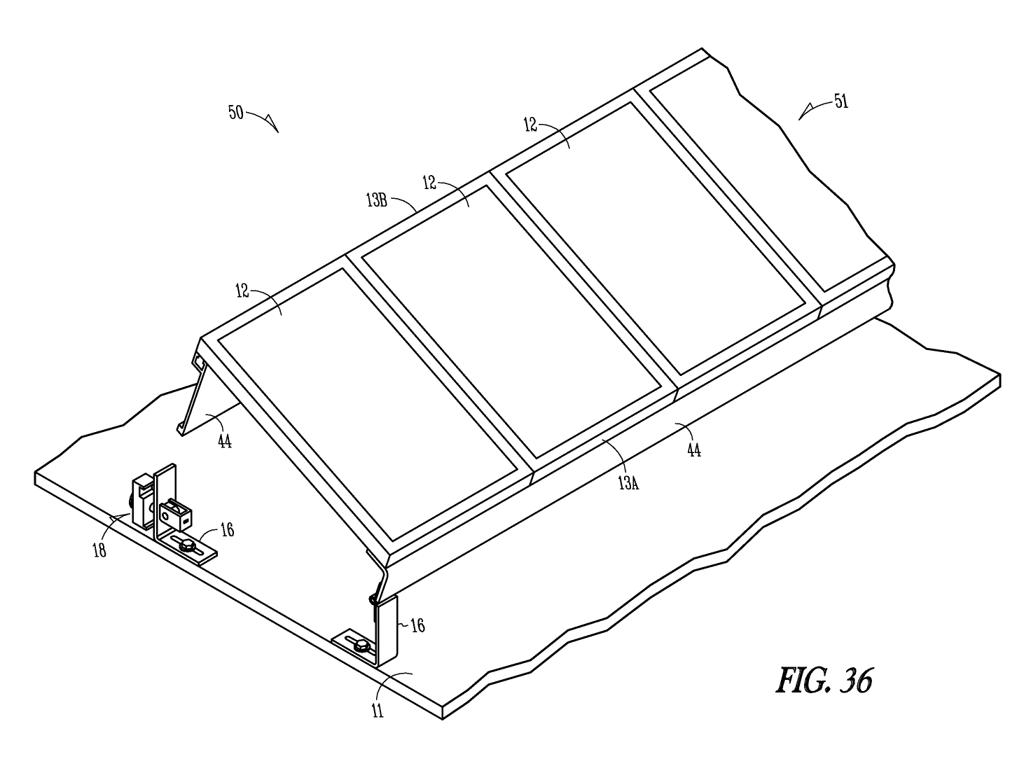

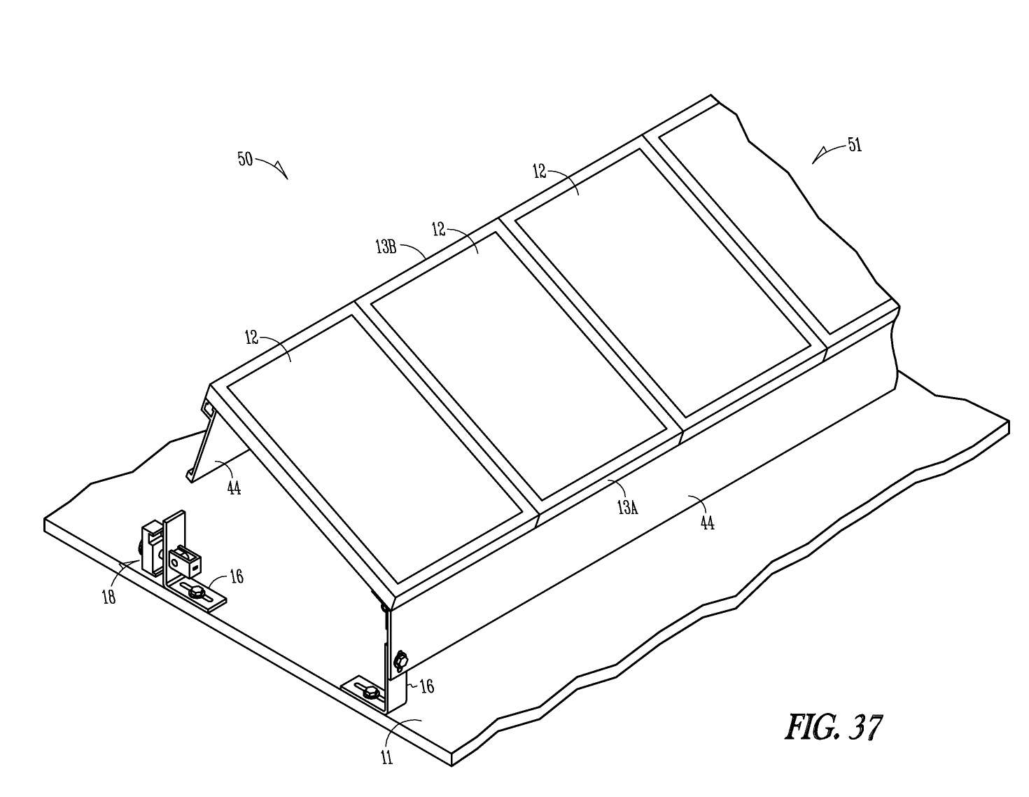

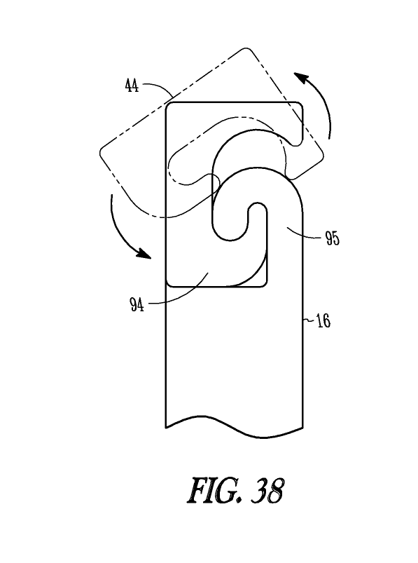

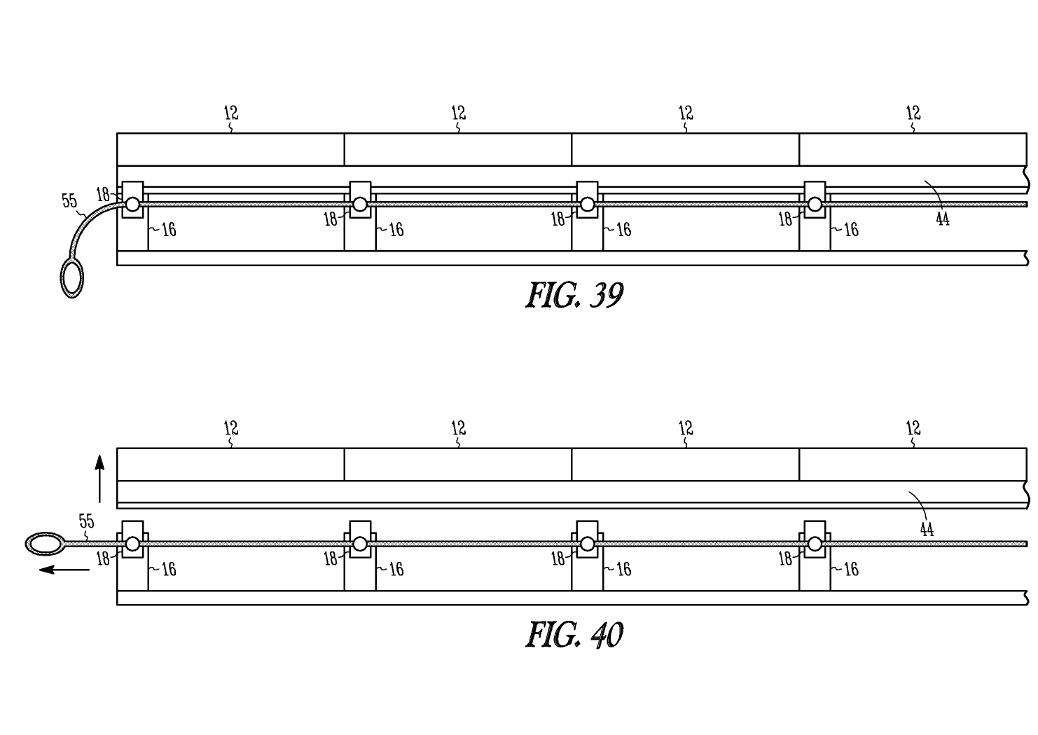

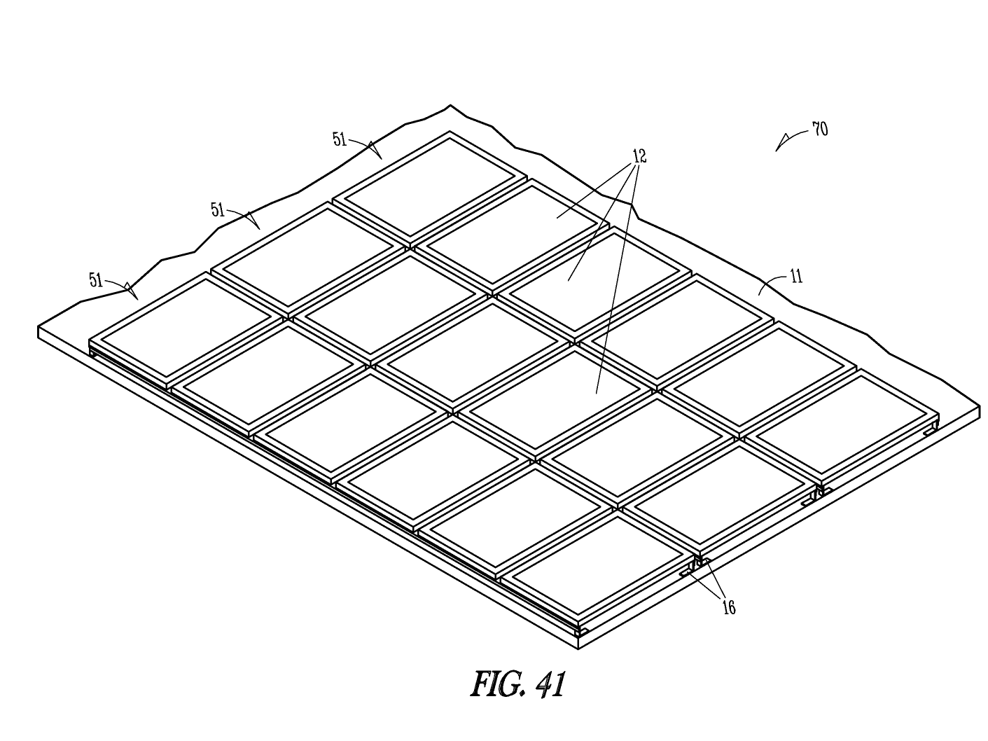

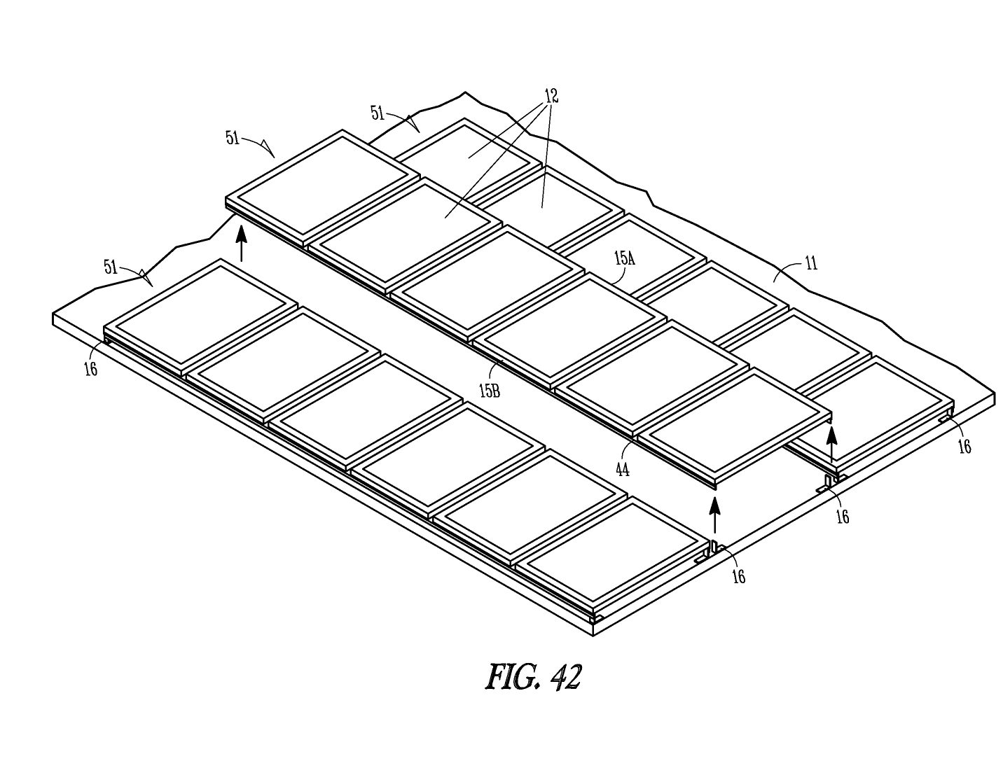

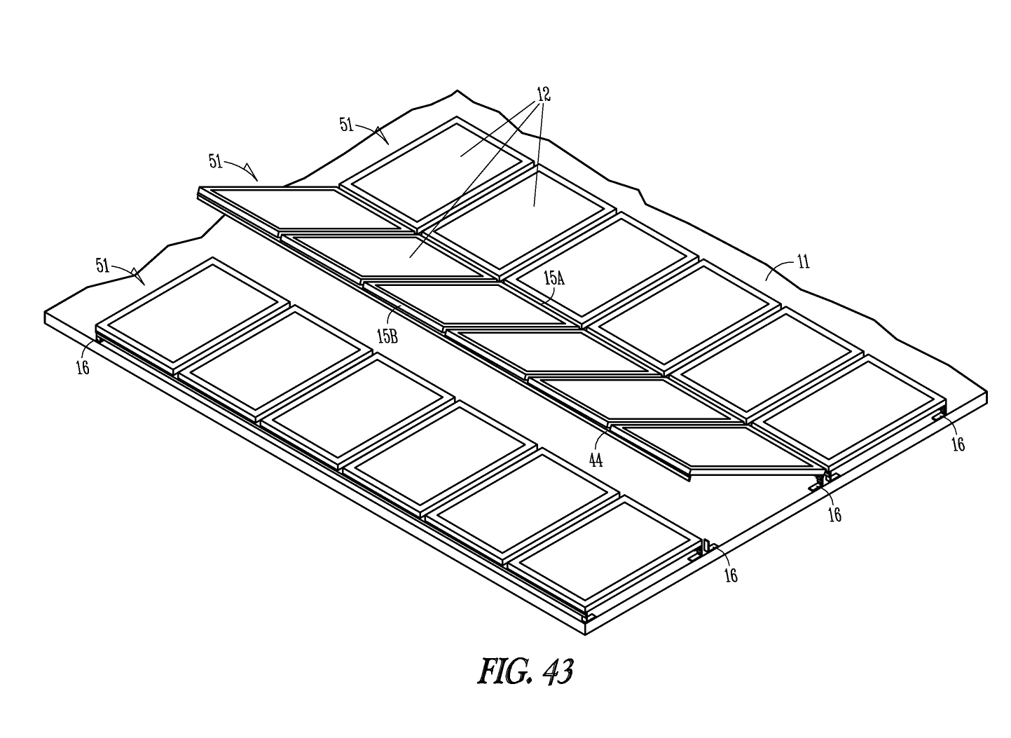

As shown in FIG. 2, firefighters 14 often need to remove solar panels 12 from a roof 11 when fighting fires. The illustrated example solar energy system 1 eliminates the need for firefighters 14 to haul, find and use an assortment of tools in order to remove one or more of the solar panels 12 during a potentially dangerous firefighting situation.

FIGS. 3 and 4 show an example solar energy system 10 that includes a solar panel 12 and a support 16 which is secured to the solar panel 12 such that the support 16 may be detached from the solar panel 12 such that the support 16 may be detached from the solar panel 12 by manually manipulating at least one of the support 16 and the solar panel 12.

In some embodiments, the support 16 may be detached from the solar panel 12 without using tools. In other embodiments, a simple tool (e.g., a screw driver) may be used to detach the support 16 from the solar panel 12.

As shown in FIGS. 3 and 4, the solar energy system 10 further includes a clamp 18 that secures the solar panel 12 to the support 16. Depending on the configuration of the solar energy system 10, the clamp 18 may be manually manipulated in order to detach the support 16 from the solar panel 12.

It should be noted that the support 16 may be adapted to be secured to a structure that includes a roof 11. In some embodiments, the support 16 may be adapted to extend through the roof 11 in order to be secured to a portion of a structure 15 that is below the roof 11.

As shown in FIGS. 3 and 4, the clamp 18 may include a cam 20 that compresses the support 16 against the solar panel 12 (or a bracket attached to the solar panel 12) such that the clamp 18 must be rotated in order to detach the solar panel 12 from the support 16. In some embodiments, the clamp 18 further includes a head 24 and a projection 26 that extends from the head 24 such that the projection 26 extends through the support 16 and the solar panel 12. The cam 20 is rotatably attached to the projection 26 such that the solar panel 12 and the support 16 may be compressed together between the head 24 and the cam 20. It should noted that the relative size and shape of the support 16, cam 20, head 24 and projection 26 will depend in part on the application where the solar energy system 10 is to be used.

In the example embodiment shown in FIGS. 3 and 4, the solar panel 12 includes a substantially straight member 30 and the support 16 includes an L-shaped bracket 32. The projection 26 extends through the straight member 30 and the L-shaped bracket 32 such that the head 24 and the cam 20 compress the straight member 30 and the L-shaped bracket 32 together. It should be noted that the relative size and shape of the straight member 30 and the L-shaped bracket 32 may be modified without departing from the scope of the present invention.

FIGS. 5 and 6 show an example embodiment where the solar energy system 10 includes an elongated member 44 such that the elongated member 44 may be detached from the support 16. It should be noted that the elongated member 44 may be integral with the solar panel 12 or secured to the solar panel 12 with a fastener. As an example, one elongated member 44 may be positioned near one edge 13A of the solar panel 12 and the other elongated member 44 may be positioned near an opposing edge 13B of the solar panel 12.

In the example embodiment shown in FIGS. 5 and 6, the support 16 includes an L-shaped bracket 40 and a mounting block 41. The mounting block 41 includes a channel 42 such that the elongated member 44 is positioned within the channel 42. The projection 26 extends through the L-shaped bracket 40, the elongated member 44 and the mounting block 41 such that the head 24 and the cam 20 are able to compress the L-shaped bracket 40, the elongated member 44 and the mounting block 41 together. It should be noted that the relative size and shape of the L-shaped bracket 40, the elongated member 44 and the mounting block 41 may be modified without departing from the scope of the present invention.

The relative number and location of the elongated members 44 will depend in part on (i) the size of the solar panels 12; (ii) the design of the supports 16; and (iii) the type of elongated members 44 that are used in the solar energy system (among other factors). Although the elongated members 44 are shown as being of a channel-type, other types of elongated members are contemplated for use in the solar energy system 10.

As shown in FIG. 7, the solar energy system 10 may further include at least one additional support 16 that is secured to the solar panel 12 such that each support 16 may be detached from the solar panel 12. It should be noted that the relative number, size, arrangement and shape of the supports 16 will depend in part on (i) the size of the solar panels 12; (ii) the design of the support 16; and (iii) the type of roof 11 where the solar energy system 10 is located (among other factors).

In the example embodiment that is illustrated in FIGS. 8 and 9, one elongated member 44 may be rotatably attached to the support(s) 16 on one side 13A of the solar panel 12 such that the solar panel 12 and elongated members 44 may be rotated about the support 16 when the elongated member 44 on the other side 13B of the solar panel 12 is detached from each of the supports 16. FIGS. 10 and 11 show a slightly different embodiment where one elongated member 44 is rotatably attached to the solar panel 12 such that the solar panel 12 may be rotated about the elongated member 44 when the other elongated member 44 and the solar panel 12 are detached from each of the respective supports 16 on the other side 13B of the solar panel 12.

FIGS. 12-13 illustrate an example embodiment of the solar energy system 10 where the clamp 18 is a first clamp 18 that secures the elongated member 44 to the support 16. The elongated member 44 includes a channel 47 such that a portion of the first clamp 18 extends through the support 16 and is contained within the channel 47 of the elongated member.

FIGS. 14-15 illustrate an example embodiment of a portion of the first clamp 18 shown in FIGS. 12-13 where the first clamp 18 includes a first U-shaped member 52 that has a base 53 and a pair of arms 54. The first clamp 18 further includes a second flat member 55 and a third U-shaped member 58 that includes a base 59 and a pair of arms 60.

A pin 61 extends between the arms 54 of the first U-shaped member 52 and through the arms 60 of the third U-shaped member 58 such that the third U-shaped member 58 is able to rotate about the pin 61 relative to the first and second members 52, 55. The arms 54 of the first U-shaped member 52 extend through an opening in the second flat member 55 and an opening 17 (see FIG. 13) in the support 16 such that the ends of the arms 54 of first U-shaped member 52 are contained with the channel 47 of the elongated member 44 (see FIG. 12). Rotation of the third U-shaped member 58 causes the ends of the arms 60 on the third U-shaped member 58 to engage the base 56 of the second flat member 55 and compress the support 16 against the elongated member 44.

It should be noted that the channel 47 in the elongated member 44 may be T-shaped and the ends of the arms 54 on the first U-shaped member may be T-shaped such that the T-shaped ends of the arms 54 fit within the T-shaped channel 47. Other embodiments are contemplated for the ends of the arms 54 and the channel 47 as long as the ends of the arms 54 are constrained by the elongated member 44.

In some embodiments, a washer 64 may be positioned between the base 56 of the second flat member 55 and the support 16 such that the arms 54 of the first U-shaped member 52 extend through the washer 64. In addition, the opening 17 in the support 16 may a slot such that the elongated member 44 may be adjusted relative to the support 16 by maneuvering the arms 54 of the first U-shaped member 52 within the slot 17 when the clamp 18 is not compressing the support 16 against the elongated member 44. It should be noted that washer 64 may be a Belville washer that provides a spring force to the second flat member 55.

As shown in FIGS. 12 and 13, the support 16 may include an L-shaped bracket 66 and a substantially straight bracket 67 that is connected to the L-shaped bracket 66. The L-shaped bracket 66 is secured to the elongated member 44 by the first clamp 18.

In some embodiments, the substantially straight bracket 67 may be adapted to be secured to a structure (e.g., a roof and/or flashing 99 that is secured to a roof) where the solar energy system 10 is mounted. In addition, the solar energy system 10 may further include a second clamp 68 that secures the L-shaped bracket 67 to the substantially straight bracket 66.

FIGS. 16-19 show an example embodiment of the solar energy system 10 where the solar panel 12 is snap-fit onto the support 16. In the embodiment shown in FIG. 16, the solar panel 12 includes a hook 70 and the support 16 includes a cylindrical member 71 such that the hook 70 is snapped onto the cylindrical member 71. In the embodiment shown in FIG. 17, an elongated member 44 is connected to the solar panel 12 such that the elongated member 44 includes the hook 70. In the embodiment shown in FIG. 18, an elongated member 44 is connected to the support 16 such that the elongated member 44 includes the cylindrical member 71 and the solar panel 12 includes the hook 70. In the embodiment shown in FIG. 19, the support 16 includes the hook 70 and the solar panel 12 includes the cylindrical member 71.

FIGS. 20-23 show an example embodiment of the solar energy system 10 where the solar energy system 10 further includes a latch 72 that secures the support 16 to one side 13A of the solar panel 12. In some embodiments, the latch 72 may include a stop 73 that projects from a body 74 such that the stop 73 engages the solar panel 12 in order to secure the solar panel 12 (FIG. 20).

The latch 72 may include a spring 75 which biases the stop 73 such that the stop 73 projects from the body 74 yet allows the stop 73 to regress into the body 74 when force is applied to the stop 73. As shown in FIG. 21, the latch 72 may include a handle 76 that is adapted to retract the stop 73 into the body 74 and permit the solar panel 12 to be detached from the support 16.

FIG. 22 shows an example embodiment of the solar energy system 10 where an elongated member 44 is connected to the solar panel 12 such that the latch 72 secures the elongated member 44 to the support 16. FIG. 23 shows an example embodiment of the solar energy system 10 where an elongated member 44 is connected to the support 16 such that the latch 72 secures the elongated member 44 to the solar panel 12.

FIG. 24 shows an example embodiment of the solar energy system 10 where the solar energy system 10 further includes a latch 72 that secures the support 16 to one side 13A of the solar panel 12 and at least one additional support 16 that is positioned adjacent to an opposing side 13B of the solar panel 12. The additional support 16 includes a slot 78 and the solar panel 12 includes a tab 79 on the opposing side 13B of the solar panel 12 to the latch 72 such that the opposing side 13B of the solar panel 12 is secured to the additional support 16 by inserting the tab 79 on the solar panel 12 into the slot 78 on the additional support 16.

FIG. 25 shows an example embodiment of the solar energy system 10 where an elongated member 44 is connected to the solar panel 12 such that the tab 79 is on the elongated member 44 which is inserted into the slot 78 in the support 16. FIG. 26 shows an example embodiment of the solar energy system 10 where an elongated member 44 is connected to the support 16 such that the tab 79 is on the solar panel 12 which is inserted into the slot 78 in the elongated member 44.

FIG. 27 shows an example embodiment of the solar energy system 10 where the solar energy system 10 further includes a mechanism 83 (e.g., a latch) that is operated to secure the support 16 to the solar panel 12. It should be noted that mechanism 83 may be any device that can used to secure the support 16 to the solar panel 12 such that the support 16 may be detached from the solar panel 12.

In the embodiment that is illustrated in FIGS. 27, the solar energy system 10 further includes a barrier 84 that obstructs operation of the mechanism 83 such that the barrier 84 must be circumvented in order to operate the mechanism 83 and detach the solar panel 12 from the support 16.

As an example, the barrier 84 may be an enclosure which contains the mechanism 83 such that the enclosure must be opened in order to expose the mechanism 83. In addition, the barrier 84 may include (i) a glass portion 86 that must be broken in order to expose the mechanism 83; and (ii) alphanumeric information 87 that instructs a user to break the glass portion 86 of the enclosure 84 in order to expose the mechanism 83.

In some embodiments, an elongated member (e.g., elongated member 44 as described above) may be connected to the solar panel 12 such that mechanism 83 is operated to secure the elongated member 44 to the support 16. In other embodiments, an elongated member may be connected to the support 16 such that mechanism 83 is operated to secure the elongated member to the solar panel 12.

It should be noted that the barrier 84 may take a variety of forms and actually form part of the mechanism 83. FIG. 28 shows an example embodiment where the barrier 84 is also the mechanism 83 that secures the solar panel 12 to the support 16. The mechanism/barrier 83, 84 includes a portion 85 that is weaker than the rest of the barrier 84 such that the barrier 84 breaks at the portion 85 when a force is applied to the barrier 84 (e.g., by striking the portion 85 with a hand or foot or using a tool to break the portion). Once the portion 85 of the barrier 84 is broken, the support 16 may be detached from the solar panel 12.

FIGS. 29-31 show an example embodiment of the solar energy system 10 that includes an additional solar panel 12 and a plurality of supports 16. A first elongated member extends between at least two supports 16 on one side 13A of the solar panels 12 and a second elongated member 44 extends between at least two supports 16 on an opposing side 13B of the solar panels 12. The first elongated member 44 includes a first channel 86 that receives one side 13A of the solar panels 12 and the second elongated member 44 includes a second channel 89 that receives the opposing side 13B of the solar panels 12. The solar panels 12 are able to slide back and forth past one another within the first channel 86 and the second channel 89 when the solar panels 12 are detached from the first and second elongated members 44 (e.g., by releasing clamps 18).

FIGS. 32-34 show an example embodiment of the solar energy system 10 which includes an additional solar panel 12 such that the solar panels 12 are rotatably attached together. A first elongated member 44 extends between at least two supports 16 on one side 13A of the solar panels 12 and a second elongated member 44 extends between at least two supports 16 on an opposing side 13B of the solar panels 12. The first elongated member 44 includes a first channel 86 that receives one side 13A of the solar panels 12, and the second elongated member 44 includes a second channel 89 that receives the opposing side 13B.

One corner 90A of each solar panel 12 is able to slide back and forth within the first channel 86 and an adjacent corner 90B of each solar panel 12 is able to slide back and forth within the second channel 89 such that the solar panels 12 can be folded together (see FIG. 33) when the solar panels 12 are detached from the first and second elongated members 44 (e.g., by releasing clamps 18).

In some embodiments, the solar panels 12 are rotatably attached to one another using a door-type hinge. Although it should be noted that the solar panels 12 may be rotatably attached together in any manner that permits rotation of the solar panels 12 relative to one another.

It should be noted that embodiments are contemplated which include a biasing member (e.g., a spring, pneumatic cylinder, counter-weight) that acts on the solar panel 12 to move the solar panel 12 relative to the roof once the solar panel 12 is detached from the elongated member(s) 44 and/or the support(s) 16. As an example, one or more clamps 18 may be maneuvered to detach a solar panel 12 from an elongated member 44 so that a spring (not shown) applies a biasing force to the solar panel. The biasing force serves to move the solar panel 12 and expose that portion of the roof which was under the solar panel 12.

FIG. 35 illustrates another example solar energy system 50. The solar energy system 50 includes a plurality of solar panels 12 that are arranged in a row 51. The solar energy system 50 further includes at least one support 16 that is secured to at least one of the solar panels 12 such that the support 16 may be detached from the solar panels 12 by manually manipulating at least one of the support(s) 16 and the solar panels 12.

In some embodiments, the support(s) 16 may be detached from the solar panes 12 without using tools. In other embodiments, a simple tool (e.g., a screw driver) may be used to detach the support(s) 16 from the solar panels 12.

It should be noted that in some embodiments each of the solar panels 12 in the row 51 of solar panels 12 may be interconnected. In addition, depending on the size and shape of the support 16, the support 16 may be secured to each of the solar panels 12 such that the support 16 may be detached from each of the solar panels 12. FIG. 35 shows an example embodiment where the solar energy system 50 includes supports 16 which are positioned at the end of the row 51 such that the supports 16 may be detached from the row 51 of solar panels 12.

As discussed above with regard to solar energy system 10, the supports 16 in the solar energy system 50 may be adapted to be secured to a structure that includes a roof 11. In some embodiments, the supports 16 may be adapted to extend through the roof 11 in order to be secured to a portion of a structure that is below the roof 11.

In some embodiments, one or more clamps 18 may be used to secure the solar panels 12 to one or more of the supports 16. It should be noted that the clamps 18 may be similar to any of the clamps 18 that are described above. The number, type, arrangement and style of the clamps 18 will depend in part on (i) the size and design of the solar panels 12; (ii) the size and design of the supports 16; and (iii) the type of roof 11 where the solar energy system 50 is located (among other factors).

The solar energy system 50 may include an elongated member 44 which is attached to one or more of the supports 16 and connected to each of the solar panels 12 in the row 51 of solar panels 12 such that the elongated member 44 may be detached from the support(s) 16. In addition, the solar energy system 50 may include at least one additional elongated member 44 which is connected to each of the solar panels 12 in the row 51 of solar panels 12 and is secured to one or more supports 16.

In some embodiments, the additional elongated member(s) 44 may be detached from the supports 16. In addition, one elongated member 44 may be positioned near one edge 15A of the row 51 of solar panels 12 and the other elongated member 44 may be positioned near the opposing edge 15B of the row 51 of solar panels 12.

In the example embodiment that is illustrated in FIG. 36, one elongated member 44 may be rotatably attached to some of the supports 16 such that the row 51 of solar panels 12 and the other elongated member 44 may be rotated about the supports 16 when the row 51 of solar panels 12 and the other elongated member 44 are detached from the other supports 16. FIG. 37 shows a slightly different embodiment where the row 51 of solar panels 12 is rotatably attached to one of the elongated members 44 such that the row 51 of solar panels 12 may be rotated about the elongated member 44 when the other elongated member 44 and the row 51 of solar panels 12 are detached from each of the supports 16.

In some embodiments, the solar panels 12 may be rotatably attached to the elongated member 44 in any manner that facilitates rotation of the solar panels 12 relative to the elongated member 44 while in other embodiments the elongated member 44 may be rotatably attached to the supports 16 in any manner that facilitates rotation of the elongated member 44 relative to the supports 16. In addition, in those embodiments that do not include elongated members 44, the solar panels 12 may be rotatably attached to the supports 16 in any manner that facilitates rotation of the solar panels 12 relative to the supports 16. Some example items that may be used to rotatably connect the solar panels 12, elongated members 44 and/or supports 16 together include door-type hinges as well as living hinges.

FIG. 38 illustrates another example configuration for rotatably attaching the (i) solar panels 12 to the elongated members 44; (ii) elongated members 44 to the supports 16; (iii) or solar panels 12 to the supports 16. In the example embodiment that is illustrated in FIG. 38, at least one of the elongated members 44 includes a hook-shaped edge 94 and the support 16 includes a hook-shaped edge 95 that engages the hook-shaped edge 94 on the elongated member 44. As shown in FIG. 38, the hook-shaped edges 94, 95 engage each other in such a way that permits the elongated member 44 and the support 16 to become attached to one another.

In some embodiments, the solar energy system 50 includes a mechanism which is connected to some of the clamps 18. Maneuvering the mechanism disengages each clamp 18 that is connected to the mechanism in order to detach the elongated member 44 from the supports 16. FIGS. 39 and 40 show an example embodiment where the mechanism is a cord 55 that is pulled to maneuver each clamp 18 and detach the elongated member 44 from the supports 16.

In other embodiments, the clamps 18 may connect the elongated members 44 to the solar panels 12 such that pulling a cord 55 detaches one side of the solar panels from the elongated member 44. It should be noted that mechanisms may be attached to both sides of the row 51 of solar panels 12 such that one or both sides of the row 51 of solar panels 12 may be detached from the elongated members 44 and/or supports 16 depending on the configuration of the solar energy system 50.

FIG. 41 illustrates another example solar energy system 70 that includes a plurality of solar panels 12 which are arranged in a plurality rows 51. The solar energy system 70 further includes a plurality of supports 16 that are secured to some of the rows 51 of solar panels 12 such that the solar panels 12 may be detached from the supports 16 by manually manipulating at least one of the supports 16 and the solar panels 12.

In some embodiments, the support 16 may be detached from the solar panel 12 without using tools. In other embodiments, a simple tool (e.g., a screw driver) may be used to detach the support 16 from the solar panel 12. In addition, depending on the configuration of the solar energy system 70, the solar panels 12 in each row 51 may be interconnected, and/or one or more of the rows 51 of solar panels 12 may be interconnected.

One or more clamps may be used to secure the solar panels 12 (or the rows 51 of solar panels 12) to one or more of the supports 16. It should be noted that the clamps may be similar to any of the clamps 18 that are described above. The number, type, arrangement and style of the clamps will depend in part on (i) the size and design of the solar panels 12; (ii) the size and design of the supports 16; (iii) the number of rows 51 of solar panels 12; and (iv) the type of roof 11 where the solar energy system 70 is located (among other factors).

FIG. 42 shows an example embodiment where both sides 13A, 13B of one of the rows 51 of solar panels have been detached from the supports 16 on the roof 11. FIG. 43 shows a similar example embodiment where one side 13B of one of the rows 51 of solar panels has been detached from the supports 16 on the roof 11 and the other side 13A is still rotatably attached to the supports 16.

As discussed above with regard to solar energy systems 10, 50, the supports 16 in the solar energy system 70 may be adapted to be secured to a structure that includes a roof 11. In some embodiments, the supports 16 may be adapted to extend through the roof 11 in order to be secured to a portion of a structure that is below the roof 11.

In some embodiments, one or more elongated members 44 may be attached to one or more of the supports 16 such that each of the solar panels 12 in a row 51 of solar panels 12 as well as the elongated members 44 may be detached from the support(s) 16. As discussed above with regard to FIG. 35, one elongated member 44 may be positioned near one edge 13A of each row 51 of solar panels 12 and another elongated member 44 may be positioned near the opposing edge 13B of each row 51 of solar panels 12. It should be noted that the rows 51 in the solar energy system 70 may be similar to any of rows 51 that are described above with reference to FIGS. 35-37.

The solar energy system 70 may include one or more mechanisms that are connected to some of the clamps such that maneuvering one of the mechanisms maneuvers the respective clamps to detach one of the elongated members 44 from the respective supports 16 (see, e.g., FIGS. 39 and 40). As discussed above, the mechanism may be a cord that is pulled to maneuver the respective clamps and detach the elongated member 44 from the respective supports 16.

In other embodiments, the respective clamps may connect the elongated members 44 to the solar panels 12 such that pulling a cord detaches one side of one of the rows 51 of solar panels 12 from an elongated member 44. The mechanisms may also be attached to both sides of each row 51 of solar panels 12 such that one or both sides of each row 51 of solar panels 12 may be detached from the respective elongated members 44 and/or supports 16 by one or more mechanisms.

It should be noted that the mechanisms (e.g., cords 55) may be arranged to detach rows or columns of an array. In addition, the solar energy system 70 may include multiple mechanisms such that each mechanism detaches individual solar panels 12. Other embodiments are contemplated where a single mechanism detaches individual solar panels 12, multiple solar panels 12 or multiple rows/columns of solar panels 12.

Thus, a solar energy system has been described. Although the present invention has been described with reference to specific exemplary embodiments, it will be evident that various modifications and changes may be made to these embodiments without departing from the broader spirit and scope of the invention. Accordingly, the specification and drawings are to be regarded in an illustrative rather than a restrictive sense.

What is claimed is:

1. A solar energy system comprising:
a solar panel; and
a support secured to the solar panel such that the support may be detached from the solar panel by manually manipulating at least one of the support and the solar panel.

2. The solar energy system of claim 1 wherein the support may be detached from the solar panel without using tools.

3. The solar energy system of claim 1 wherein the support may be detached from the solar panel using tools.

4. The solar energy system of claim 1 further comprising a clamp that secures the solar panel to the support.

5. The solar energy system of claim 4 wherein the clamp includes a cam that compresses the support against the solar panel such that the clamp must be rotated in order to detach the solar panel from the support.

6. The solar energy generating system of claim 5 wherein the clamp further includes a head and projection extending from the head such that the projection extends through the support and the solar panel with the cam being rotatably attached to the projection, the solar panel and the support being compressed together between the head and the cam.

7. The solar energy generating system of claim 6 wherein the solar panel includes a substantially straight member and the support includes an L-shaped bracket, the projection extending through the straight member and the L-shaped bracket such that the head and the cam compress the straight member and the L-shaped bracket together.

8. The solar energy generating system of claim 1 wherein the support is adapted to be secured to a structure that includes a roof.

9. The solar energy generating system of claim 1 wherein the support is adapted to extend through a roof to be secured to a portion of a structure that is below the roof.

10. The solar energy system of claim 1 wherein the solar panel includes an elongated member such that the elongated member may be detached from the support.

11. The solar energy system of claim 10 wherein the elongated member is integral with the solar panel.

12. The solar energy system of claim 10 wherein the elongated member is secured to the solar panel with a fastener.

13. The solar energy system of claim 10 further comprising at least one additional support that is secured to the solar panel such that each support may be detached from the solar panel.

14. The solar energy system of claim 13 wherein the solar panel includes another elongated member such that each elongated member is secured to at least one of the supports.

15. The solar energy system of claim 14 wherein one elongated member is positioned near one edge of the solar panel and the other elongated member is positioned near an opposing edge of the solar panel.

16. The solar energy system of claim 15 wherein one elongated member is rotatably attached to at least one of the supports such that the solar panel and the other elongated member may be rotated about the supports when the other elongated member is detached from the other supports.

17. The solar energy system of claim 15 wherein one elongated member is rotatably attached to the solar panel such that the solar panel may be rotated about the elongated member when the solar panel is detached from the other elongated member.

18. The solar energy generating system of claim 10 wherein the support includes an L-shaped bracket and a mounting block, the mounting block including a channel such that the elongated member is positioned within the channel, the projection extending through the L-shaped bracket, the elongated member and the mounting block such that the head and the cam compress the L-shaped bracket, the elongated member and the mounting block together.

19. The solar energy generating system of claim 10 further comprising a first clamp that secures the elongated member to the support, wherein the elongated member includes a channel such that a portion of the first clamp extends through the support and is contained within the channel.

20. The solar energy generating system of claim 19 wherein the first clamp comprises:
a first U-shaped member that includes a base and a pair of arms;
a second flat member;
a third U-shaped member that includes a base and a pair of arms; and
a pin extending between the arms of the first U-shaped member and through the arms of the third U-shaped member such that the third U-shaped member is able to rotate about the pin relative to the first U-shaped member and second flat member, wherein the arms of the first U-shaped member extend through an opening in the base of the second flat member and an opening in the support such that the ends of the arms of first U-shaped member are contained with the channel of the elongated member, wherein rotation of the third U-shaped member causes the ends of the arms of the third U-shaped member to engage the base of the second flat member and compress the support against the elongated member.

21. The solar energy generating system of claim 20 wherein the channel in the elongated member is T-shaped and ends of the arms on the first U-shaped member are T-shaped such that the T-shaped ends of the arms on the first U-shaped member fit within the T-shaped channel in the elongated member.

22. The solar energy generating system of claim 20 further comprising a washer positioned between the base of the second flat member and the support such that the arms of the first U-shaped member extend through the washer.

23. The solar energy generating system of claim 22 wherein the washer is a Belville washer that provides a spring force to the second flat member.

24. The solar energy generating system of claim 20 wherein the opening in the support is a slot such that the elongated member may be adjusted relative to the support when the clamp is not compressing the support against the elongated member.

25. The solar energy generating system of claim 20 wherein the support includes an L-shaped bracket and a substantially straight bracket that is connected to the L-shaped bracket, wherein the L-shaped bracket is secured to the elongated member by the first clamp.

26. The solar energy generating system of claim 25 wherein the substantially straight bracket is adapted to be secured to a structure where the solar energy system is mounted.

27. The solar energy generating system of claim 26 further comprising a second clamp that secures the L-shaped bracket to the substantially straight bracket.

28. The solar energy generating system of claim 1 wherein the solar panel is snap-fit onto the support.

29. The solar energy generating system of claim 28 wherein the solar panel includes a hook and the support includes a cylindrical member that is snapped into the hook.

30. The solar energy generating system of claim 29 further comprising an elongated member that is connected to the solar panel such that the elongated member includes the hook.

31. The solar energy generating system of claim 29 further comprising an elongated member that is connected to the support such that the elongated member includes the cylindrical member.

32. The solar energy generating system of claim 28 wherein the support includes a hook and the solar panel includes a cylindrical member that is snapped into the hook.

33. The solar energy generating system of claim 1 further comprising a latch that secures the support to one side of the solar panel.

34. The solar energy generating system of claim 33 wherein the latch includes a stop that projects from a body, the stop engaging the solar panel to secure the solar panel.

35. The solar energy generating system of claim 34 wherein the latch includes a spring which biases the stop such that the stop projects from the body yet allows the stop to regress into the body when force is applied to the stop.

36. The solar energy generating system of claim 35 wherein the latch includes a handle that is adapted to apply a force to the stop in order to retract the stop into the body and permit the solar panel to be detached from the support.

37. The solar energy generating system of claim 33 further comprising an elongated member that is connected to the solar panel such that the latch secures the elongated member to the support.

38. The solar energy generating system of claim 33 further comprising an elongated member that is connected to the support such that the latch secures the elongated member to the solar panel.

39. The solar energy generating system of claim 1 further comprising:
a latch that secures the support to one side of the solar panel; and
at least one additional support that includes a slot, wherein the solar panel includes a tab on an opposing side of the solar panel to the latch such that the opposing side of the solar is secured to the additional support by inserting the tab on the solar panel into the slot on the additional support.

40. The solar energy generating system of claim 39 further comprising an elongated member that is connected to the solar panel such that the tab is on the elongated member which is inserted into the slot in the support.

41. The solar energy generating system of claim 39 further comprising an elongated member that is connected to the support such that the tab on the solar panel is inserted into the slot in the elongated member.

42. The solar energy generating system of claim 1 further comprising:
a mechanism that is operated to secure the support to the solar panel and detach the support from the solar panel; and
a barrier that obstructs operation of the mechanism such that the barrier must be circumvented in order to operate the mechanism and detach the solar panel from the support.

43. The solar energy generating system of claim 42 wherein the barrier is an enclosure that contains the mechanism such that the barrier must be opened in order to expose the mechanism.

44. The solar energy generating system of claim 43 wherein the enclosure includes a glass portion that must be broken in order to expose the mechanism.

45. The solar energy generating system of claim 44 wherein the enclosure includes alphanumeric information that instructs a user to break the glass portion of the enclosure in order to expose the mechanism.

46. The solar energy generating system of claim 42 wherein a portion of the barrier is broken in order to operate the mechanism.

47. The solar energy generating system of claim 46 wherein the portion of the barrier that is broken is weaker than the rest of the barrier such that the barrier breaks at the portion when a force is applied to the barrier.

48. The solar energy system of claim 1 further comprising:
an additional solar panel;
a plurality of supports;
a first elongated member extending between at least two supports on one side of the first and second solar panels; and
a second elongated member extending between at least two supports on an opposing side of the first and second solar panels, the first elongated member including a first channel that receives one side of the first and second solar panels and the second elongated member including a second channel that receives the opposing side of the first and second solar panels, wherein the solar panels are able to slide back and forth past one another within the first and second channels on the first and second elongated members when the solar panels are detached from the first and second elongated members.

49. The solar energy system of claim 1 further comprising:
an additional solar panel rotatably attached to the other solar panel;
a plurality of supports;
a first elongated member extending between at least two supports on one side of the solar panels; and
a second elongated member extending between at least two supports on an opposing side of the solar panels, the first elongated member including a first channel and the second elongated member including a second channel, wherein one corner of each solar panel is able to slide back and forth within the first channel and an adjacent corner of each solar panel is able to slide back and forth within the second channel such that the solar panels can be folded together when the first and second solar panels are detached from the first and second elongated members.

50. The solar energy system of claim 49 wherein the solar panels are rotatably attached to one another using a door-type hinge.

51. A solar energy system comprising:
a plurality of solar panels that are arranged in a row; and
a support secured to at least one of the solar panels such that the support may be detached from the solar panels by manually manipulating at least one of the support and the solar panels.

52. The solar energy system of claim 51 wherein the support may be detached from the solar panels without using tools.

53. The solar energy system of claim 51 wherein the support may be detached from the solar panels using tools.

54. The solar energy system of claim 51 wherein the solar panels are interconnected.

55. The solar energy system of claim 51 further comprising a plurality of supports where each support is secured to at least one of the solar panels such that the supports may be detached from the solar panels.

56. The solar energy system of claim 51 further comprising a clamp that secures the solar panels to the support.

57. The solar energy generating system of claim 51 wherein the support is adapted to be secured to a structure that includes a roof.

58. The solar energy generating system of claim 51 further comprising:
an elongated member attached to the support and connected to each of the solar panels; and
at least one additional support that is secured to the elongated member such that the supports may be detached from the elongated member.

59. The solar energy system of claim 58 further comprising an additional elongated member that is connected to each of the solar panels and is secured to at least one of the supports.

60. The solar energy system of claim 59 wherein the additional elongated member may be detached from the support.

61. The solar energy system of claim 59 wherein one elongated member is positioned near one of the edges of the solar panels and the other elongated member is positioned near opposing edges of the solar panels.

62. The solar energy system of claim 61 wherein the additional elongated member is rotatably attached to some of the supports such that the solar panels and the elongated members may be rotated about some of the supports when one of the elongated members is detached from the other supports.

63. The solar energy system of claim 61 wherein the additional elongated member is rotatably attached to the solar panels such that the solar panels may be rotated about the additional elongated member when the solar panels are detached from the other elongated member.

64. The solar energy system of claim 58 further comprising at least one additional clamp such that each support is secured to the elongated member with a clamp.

65. The solar energy system of claim 64 wherein each clamp includes a cam that compresses one of the supports against the elongated member such that each clamp must be rotated in order to detach the elongated member from the supports.

66. The solar energy system of claim 64 further comprising a mechanism which is connected to each clamp such that maneuvering the mechanism disengages each clamp in order to detach the elongated member from the supports.

67. The solar energy system of claim 66 wherein the mechanism is a cord that is pulled to maneuver each clamp and detach the elongated member from the supports.

68. A solar energy system comprising:
a plurality of solar panels that are arranged in a plurality rows; and
a plurality of supports secured to some of the solar panels such that the supports may be detached from the solar panels by manually manipulating at least one of the supports and the solar panels.

69. The solar energy system of claim 68 wherein the supports may be detached from the solar panels without using tools.

70. The solar energy system of claim 68 wherein the supports may be detached from the solar panels using tools.

71. The solar energy system of claim 70 wherein the solar panels are interconnected.

72. The solar energy system of claim 70 further comprising a plurality of clamps that secure the solar panels to the supports.

73. The solar energy generating system of claim 70 further comprising a plurality of elongated members that are attached to the supports and connected to each of the solar panels in a row of solar panels such that each elongated member may be detached from the supports.

74. The solar energy system of claim 73 wherein two supports are secured to each elongated member such that one support is near one end of each elongated member and another support is near an opposing end of the elongated member.

75. The solar energy system of claim 73 wherein two elongated members are secured to each row of solar panels such that one elongated member is positioned near one edge of each row of solar panels and the other elongated member is positioned near an opposing edge of each row of solar panels.

76. The solar energy system of claim 72 further comprising a plurality of mechanisms, each of the mechanisms being connected to at least one of the clamps such that maneuvering the mechanisms maneuvers the clamps in order to detach the elongated members from the supports that are connected to the respective elongated members.

77. The solar energy system of claim 76 wherein each mechanism includes a cord that is pulled to maneuver each clamp in order to detach the elongated member from the supports.
